(19) United States
(12) Patent Application Publication
(10) Pub. No.: US 2026/0074682 A1
(43) Pub. Date: Mar. 12, 2026

(54) SYSTEM AND METHODS FOR CLOCK PULSE GENERATION

(71) Applicant: CIENA CORPORATION, Hanover, MD (US)

(72) Inventors: Naftali Weiss, East York (CA); Jacob Pike, Nepean (CA); Philip Flemke, Stittsville (CA); Michael Sawires, Ottawa (CA); Shai Bonen, Toronto (CA); Euhan Chong, Kanata (CA)

(73) Assignee: CIENA CORPORATION, Hanover, MD (US)

(21) Appl. No.: 19/393,711

(22) Filed: Nov. 19, 2025

Related U.S. Application Data
(63) Continuation-in-part of application No. PCT/US2024/055675, filed on Nov. 13, 2024.
Application No. PCT/US2024/055675 is a continuation of application No. 18/509,910, filed on Nov. 15, 2023, now Pat. No. 12,249,990.

(51) Int. Cl. H03K 3/017; H03K 21/17; H03K 21/40; H03L 7/08

(52) U.S. Cl. CPC H03K 3/017; H03K 21/17; H03K 21/40; H03L 7/0807

(57) ABSTRACT

Aspects of the subject disclosure may include, for example, a track-and-hold sampling circuit, having: a duty-cycle limiter that generates a clock signal having a duty cycle that is less than 100% from three out of four clock signals; and a sampling circuit comprising complementary positive and negative input gates that track and sample data input signals, wherein the sampling circuit generates sampled data signals, wherein the complementary positive and negative input gates are coupled to the clock signal. Other embodiments are disclosed.

### CROSS REFERENCE TO RELATED APPLICATIONS

The subject disclosure is a Continuation-In-Part of International Patent Application No. PCT/US2024/055675, filed on Nov. 13, 2024, which claims the benefit of and priority to U.S. patent application Ser. No. 18/509,910, filed on Nov. 15, 2023, now U.S. Pat. No. 12,249,990. U.S. Pat. No. 12,249,990 is related to U.S. patent application Ser. No. 18/060,787 entitled, “Method and Apparatus for Clock and Data Alignment that Reduces Power Consumption,” filed on Dec. 1, 2022, and U.S. patent application Ser. No. 18/509,565 entitled, “Multiphase Clock Generator,” filed on Nov. 15, 2023. Each of the aforementioned applications are incorporated by reference herein.

### FIELD OF THE DISCLOSURE

The subject disclosure relates to an apparatus and method for wideband multi-phase clock generation.

### BACKGROUND

Data center demand for greater bandwidth continues to increase thereby requiring faster optical and electrical communication hardware. However, capacity and environmental concerns place a limit on the amount of power that such communication hardware may consume. Existing data centers are equipped to handle a limited amount of power from the grid. Current estimates suggest that data centers will consume 8% of the world's total power by 2030.

To limit the total power consumed in data centers, key hardware—namely Analog-to-Digital Converters (ADCs), Digital-to-Analog Converters (DACs) and Serializer-Deserializers (SerDes)—must increase their power in proportion with their speed. For example, a 224 Gigabit Per Second (Gb/s) Very Short Reach (VSR) SerDes is expected to consume 448 mW total, which corresponds to a power efficiency of 2 Picojoules Per Bit (pJ/b).

In addition to power consumption, jitter and skew generated by a clocking path directly impacts the Signal-to-Noise and Distortion Ratio (SNDR) of the transmitted or received data. Jitter is a measure of how much a clock's edges vary between cycles. Skew is a fixed measure of how much a clock edge deviates from its ideal location. SNDR is impacted by both jitter and skew because they cause the sampling point to deviate from an ideal point in the data. The SNDR contribution due to jitter can be mathematically predicted based on the Nyquist frequency of the input data. Similarly, skew causes harmonics to appear in the output data spectrum, which further degrades the SNDR. Hence, these plural quantitative metrics: power, area, jitter, skew and SNDR, and other qualitative metrics (complexity, reliability, scalability) should be considered when designing and implementing multiphase clock generators.

### BRIEF DESCRIPTION OF THE DRAWINGS

Reference will now be made to the accompanying drawings, which are not necessarily drawn to scale, and wherein:

FIG. 1A is a block diagram illustrating an exemplary, non-limiting embodiment of a serializer-deserializer in accordance with various aspects described herein.

FIG. 1B is a block diagram illustrating an exemplary, non-limiting embodiment of a clock and data recovery loop in accordance with various aspects described herein.

FIG. 2A is a block diagram illustrating an exemplary, non-limiting embodiment of a receiver inner clock generation circuit in accordance with various aspects described herein.

FIG. 2B is a layout diagram illustrating an exemplary, non-limiting embodiment of a receiver inner clock generation circuit in accordance with various aspects described herein.

FIG. 2C comprises a chart showing a data path transfer function and simulated SNDR at select points.

FIG. 2D comprises a chart summarizing total power consumption of an inner clock generation circuit in accordance with various aspects herein.

FIG. 3A is a schematic diagram illustrating an exemplary, non-limiting embodiment of a phase rotator used in a clock and data recovery loop in accordance with various aspects described herein.

FIG. 3B is a chart illustrating a linear performance of a phase rotator in accordance with various aspects described herein.

FIG. 3C is a chart illustrating an integral non-linearity performance of a phase rotator in accordance with various aspects described herein.

FIG. 4A is a schematic diagram illustrating an exemplary, non-limiting embodiment of circuit designs for a selectable divider in accordance with various aspects described herein.

FIG. 4B is a schematic diagram illustrating resettable ring-based dividers that use CMOS elements to achieve a very wide bandwidth of operation in accordance with various aspects described herein.

FIG. 4C is a schematic diagram illustrating resettable ring-based dividers in accordance with various aspects described herein.

FIG. 4D is a schematic diagram illustrating distribution of a reset signal to multiple channels of dividers in accordance with various aspects described herein.

FIG. 4E is a layout diagram illustrating a resettable ring-based divider implemented in accordance with various aspects herein.

FIG. 4F comprises charts showing functionality of a selectable divider implemented in accordance with various aspects herein.

FIG. 5 is a schematic diagram illustrating an exemplary, non-limiting embodiment of a multipath ring oscillator injection locked frequency divider in accordance with various aspects described herein.

FIG. 6A1 is a schematic diagram illustrating an exemplary, non-limiting embodiment of a duty-cycle limiter incorporated in a track and hold sampling circuit in accordance with various aspects described herein.

FIG. 6A2 is a schematic diagram illustrating an exemplary, non-limiting embodiment of a duty-cycle limiter incorporated in a track and hold sampling circuit in accordance with various aspects described herein.

FIG. 6A3 is a schematic diagram illustrating an exemplary, non-limiting embodiment of a duty-cycle limiter incorporated in a track and hold sampling circuit in accordance with various aspects described herein.

FIGS. 6A4, 6A5 and 6A6 are schematic diagrams illustrating exemplary, non-limiting embodiments of a duty-cycle limiter incorporated in a track and hold sampling circuit without charge injection cancelation devices in accordance with various aspects described herein.

FIG. 6A7 is a schematic diagram illustrating an exemplary, non-limiting embodiment of a duty-cycle limiter incorporated in a track and hold sampling circuit with a capacitive charge injection cancelation device in accordance with various aspects described herein.

FIG. 6A8 are schematic diagrams illustrating exemplary, non-limiting embodiments of alternative duty-cycle limiters incorporated in a track and hold sampling circuit in accordance with various aspects described herein.

FIG. 6A9 is a schematic diagram illustrating an exemplary, non-limiting embodiment of a pair of duty-cycle limiters incorporated in a track and hold sampling circuit in accordance with various aspects described herein.

FIG. 6A10 is a schematic diagram and a timing diagram illustrating an exemplary, non-limiting embodiment of a duty-cycle limiter incorporated in a track and hold sampling circuit in accordance with various aspects described herein.

FIG. 6B is a timing diagram illustrating the operation of a 25% duty cycle limiter in accordance with various aspects described herein.

FIG. 6C is a layout diagram illustrating a 25% duty-cycle limiter implemented in accordance with various aspects herein.

FIG. 6D is a graph showing simulated performance of a 25% duty cycle limiter implemented in accordance with various aspects herein.

FIG. 6E is a graph showing jitter performance of a 25% duty-cycle limiter implemented in accordance with various aspects herein.

FIG. 6F bears block diagrams illustrating duty-cycle limiters that are not co-located and co-located with track and hold sampling circuits implemented in accordance with various aspects herein.

FIG. 6G is a simplified schematic diagram and a timing diagram illustrating an exemplary, non-limiting embodiment of clock signal generation and level shifting in accordance with various aspects described herein.

FIG. 6H is a schematic diagram illustrating an exemplary, non-limiting embodiment of clock signal generation and level shifting using an AC buffer in accordance with various aspects described herein.

FIG. 6I is a schematic diagram and a timing diagram illustrating an exemplary, non-limiting embodiment of clock signal generation and level shifting using two gates in accordance with various aspects described herein.

FIG. 6J is a schematic diagram and a timing diagram illustrating an exemplary, non-limiting embodiment of a circuit for triggering a level shifting clock generation circuit in accordance with various aspects described herein.

FIG. 6K is a schematic diagram and a timing diagram illustrating an exemplary, non-limiting embodiment of a level shifting clock generation circuit in accordance with various aspects described herein.

FIG. 6L is a schematic diagram and a timing diagram illustrating an exemplary, non-limiting embodiment of a level shifting clock generation circuit in accordance with various aspects described herein.

FIG. 7A is a schematic diagram illustrating an exemplary, non-limiting embodiment of a rank 2 phase rotator in accordance with various aspects described herein.

FIG. 7B is a layout diagram illustrating a rank 2 phase rotator implemented in accordance with various aspects herein.

FIG. 7C comprises charts showing differential non-linearity and integral non-linearity of a rank 2 phase rotator implemented in accordance with various aspects herein.

### DETAILED DESCRIPTION

The subject disclosure describes, among other things, illustrative embodiments for an inner clock generation circuit. Other embodiments are described in the subject disclosure.

One or more aspects of the subject disclosure include a track-and-hold sampling circuit, having: a duty-cycle limiter that generates a clock signal having a duty cycle that is less than 100% from three out of four clock signals; and a sampling circuit comprising complementary positive and negative input gates that track and sample data input signals, wherein the sampling circuit generates sampled data signals, wherein the complementary positive and negative input gates are coupled to the clock signal.

One or more aspects of the subject disclosure include a method for creating a duty-cycle clock signal for triggering a sampling circuit, including: applying a first clock signal to an n-type terminal of a T-gate, wherein the T-gate is a metal oxide semiconductor field effect transistor; applying a second clock signal to a p-type terminal of the T-gate; and applying a third clock signal to a gate of the T-gate, thereby creating the duty-cycle clock signal having a duty cycle that is less than 100%.

One or more aspects of the subject disclosure include a track-and-hold sampling circuit, having: a first duty-cycle limiter that generates a first clock signal having a duty cycle that is less than 100% from three clock signals out of four clock signals supplied to the first duty-cycle limiter; a second duty-cycle limiter that generates a second clock signal having a second duty cycle that is less than 100% from another three out of the four clock signals, where one of clock signals is different from the three clock signals supplied to the first duty-cycle limiter; a sampling circuit with complementary positive and negative input gates that track and sample data input signals, wherein the sampling circuit generates sampled data signals, wherein the complementary positive and negative input gates are coupled to the first duty-cycle limiter through a first inverter; and a charge injection cancelation device that receives the sampled data signals and provides output data signals, wherein the charge injection cancelation device is triggered by an output of a second inverter connected to the second duty-cycle limiter.

To limit the total power consumed in data centers, key hardware, namely ADCs, DACs and SerDes, must only increase their power at the same rate as their speed. For example, 224 Gigabit Per Second (Gb/s) Very Short Reach (VSR) SerDes are expected to consume 448-mW total which corresponds to a power efficiency of 2 Picojoules Per Bit (pJ/b).

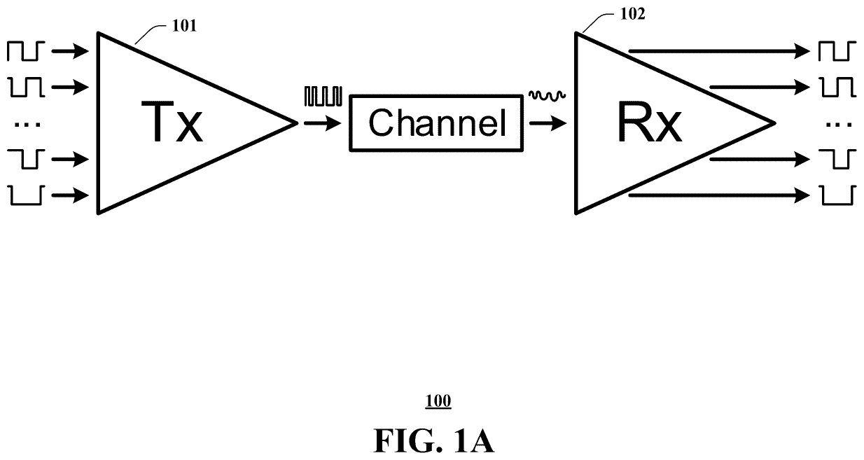

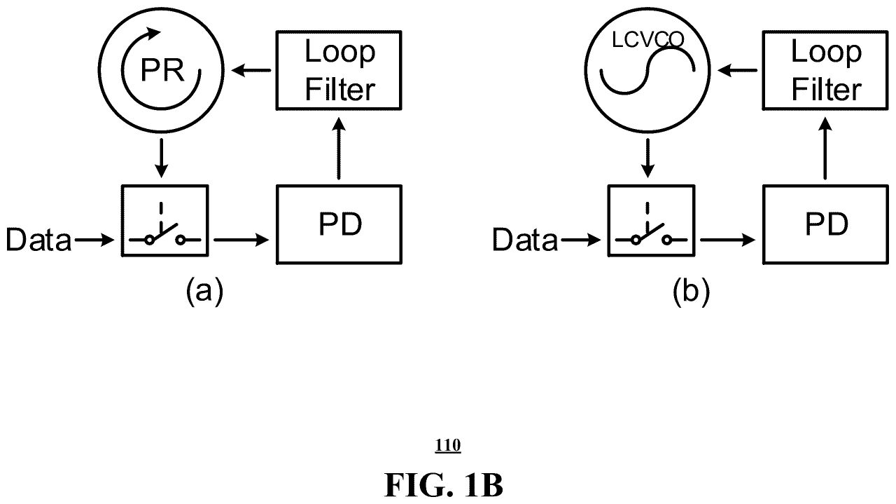

FIG. 1A is a block diagram illustrating an exemplary, non-limiting embodiment of a serializer-deserializer in accordance with various aspects described herein. As shown in FIG. 1A, SerDes 100 comprises two main blocks: a Transmitter (Tx 101) and a Receiver (Rx 102). Tx 101 serializes many low-speed data paths into one high-speed data path. Conversely, Rx 102 deserializes the high-speed data path into many low-speed data paths. As transmission speeds increase, SerDes 101 becomes increasingly reliant on high-speed medium-resolution DACs and ADCs to perform their serialization and deserialization.

The basic purpose of an ADC is to receive a single analog signal and convert it to an N-bit binary bus. Modern ADCs use time-interleaved structures where a Sampling Front-End (SFE) first deserializes the data into lower-speed paths before parallel sub-ADCs, each operating at

$$\frac{{F}_{s}}{Rank 1 \times Rank 2} ,$$

perform the actual data conversion. Fs is the overall sampling rate of the ADC. Rank 1 and Rank 2 are integers that represent the number of low-speed data paths after the first and second stages of interleaving, respectively.

Modern ADCs have sampling rates in the range of 100-to-200 Gigasamples Per Second (GS/s) and could require multi-phase clocks operating anywhere from

$$\frac{{F}_{s}}{Rank 1 \times Rank 2} to \frac{{F}_{s}}{2} .$$

As an example, a 112-GS/s ADC is required to perform PAM4 encoded data transmission at 224-Gb/s. A common approach for the ADC is Rank 1=8 and Rank 2=12, requiring eight-phase clocks at

$$\frac{{F}_{s}}{8} = 14 GHz$$

and 96-phase clocks at

$$\frac{{F}_{s}}{8 \times 12} = 1.167 GHz .$$

FIG. 1B is a block diagram illustrating an exemplary, non-limiting embodiment of a clock and data recovery loop in accordance with various aspects described herein. Another important aspect of SerDes is the clock-to-data alignment to ensure sampling is occurring at the optimal point. As shown in FIG. 1B, a clock and data recovery (CDR) loop 110 performs this alignment. The basic operation of a CDR recovers data and compares it to its sampling clock using a Phase Detector (PD). The PD outputs pulses equivalent to the phase mismatch between the data and sampling clock. These pulses are then filtered and used to drive either (a) a phase rotator (PR) or (b) an LC voltage-controlled oscillator (LCVCO).

Of these two strategies, LCVCO-based CDRs are less common because of their high power and area consumption. However, CDRs have begun using LCVCOs to meet the stringent jitter requirements. For example, 200-Gb/s SerDes implementations are expected to target <75 fs, rms random jitter. This shift is largely due to the difficulty in designing a PR that can meet this jitter requirement. However, the subject disclosure presents new concepts that make the implementation of PR-based CDRs possible at 200-Gb/s and beyond.

Clock generation is one of the biggest consumers of power and area in a wireline transceiver. Clocking is also a key factor in system performance since the jitter and skew generated by the clocking path directly impacts the Signal-to-Noise and Distortion Ratio (SNDR) of the transmitted/received data.

Another quantitative metric used to evaluate clocking architectures is the bandwidth of the entire inner clock generation. For electrical transceivers it is important to support state-of-the-art and legacy standards defined by OIF-CEI (56-Gb/s, 112-Gb/s and 224-Gb/s) and IEEE 802.3 ethernet standards (53-Gb/s, 106-Gb/s, 212-Gb/s). These standards necessitate sampling rates in the range of 26.5-GS/s to 112-GS/s. For optical transceivers it is important to support many different standards (FlexO-8-DPO, 800ZR, 800LR etc.), modulation formats (PCS-QAM, 16-QAM etc.) and oversampling ratios that may be used in the ADC/DAC (T-space, 9/8, 5/4 etc.). These applications and oversampling ratios necessitate baud rates in the range of 118-GS/s to 160-GS/s.

To support anywhere from 56 to 112 to 224 Gb/s to even twice as fast as that on the optical side with traditional methods of inner clock generation that rely on inductive peaking, tuned elements, and/or injection locked ring oscillators or delay locked loops, each of which having limited bandwidth, an entirely different topology would be needed from one data rate to another, or at the very least, inductors would need to be tuned. One circuit using such components would not support all of the data rates specified by the state-of-the-art and legacy standards.

To cover these standard data rates with a single clocking architecture, a wide bandwidth design is required. First rank interleaving is commonly performed at Fs/8 or Fs/16 in a receiver, which requires clocks ranging from 3.3125-GHz to 20-GHz at Fs/8 or 1.65625-GHz to 10-GHz at Fs/16. For some components of the clocking architecture this coverage range can be reduced with frequency dividers but the final stages of the design—those just before the data path—will need to cover the full range. Even with dividers the early stages cannot be narrowly tuned. For example, Fs/8 and Fs/16 can range from 13.25-GHz to 20-GHz and 6.625-GHz to 10-GHz to cover 106-GS/s to 160-GS/s. Since the clocking circuits cannot be narrowly tuned, both power and jitter standards are also more difficult to meet since inductive peaking cannot be used to boost amplitude and provide filtering.

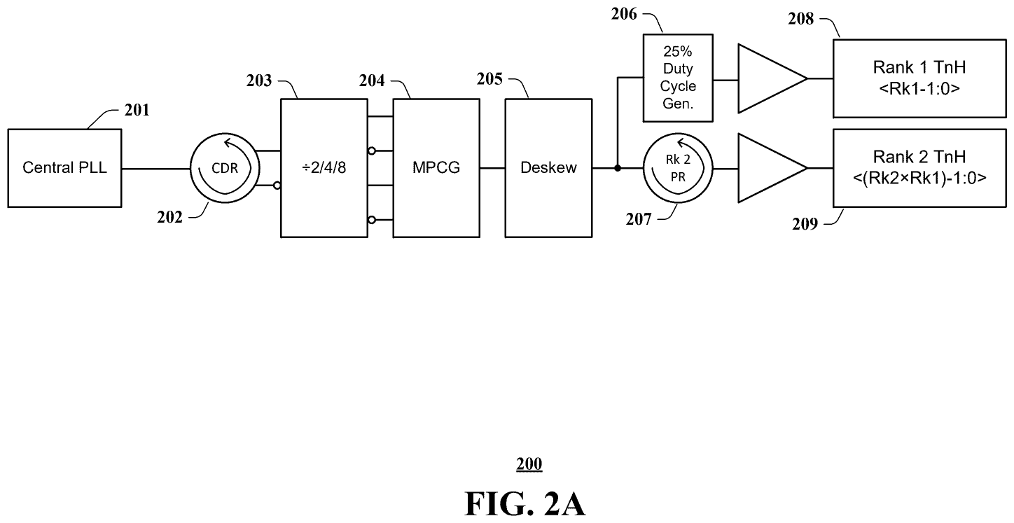

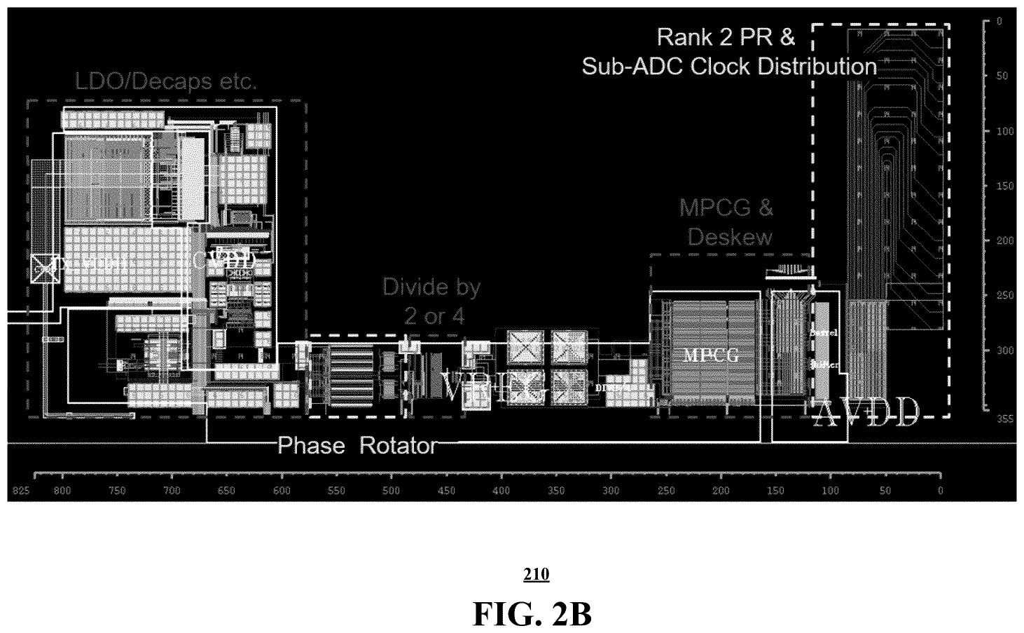

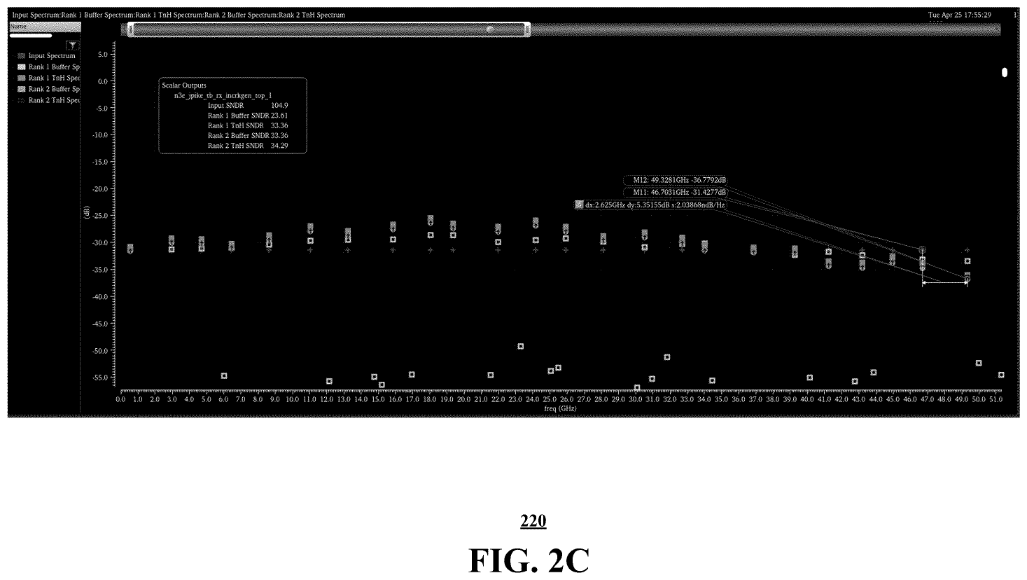

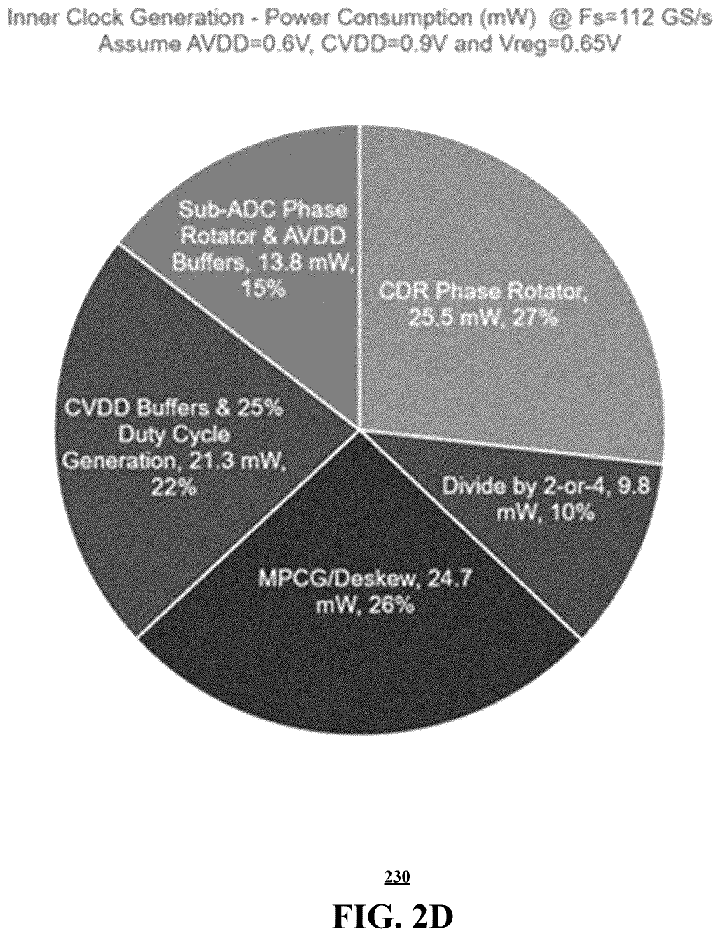

FIG. 2A is a block diagram illustrating an exemplary, non-limiting embodiment of a receiver inner clock generation circuit in accordance with various aspects described herein. As shown in FIG. 2A, receiver inner clock generation circuit 200 comprises several components including a central phase-locked loop (PLL 201), a CDR 202, a selectable frequency divider 203, a multiphase clock generator (MPCG 204), a deskew stage 205, a duty-cycle limiter 206, and a rank 2 phase rotator (PR 207). Also illustrated are rank 1 and rank 2 track-and-hold (TnH) sampling circuits 208, 209, respectively, with preceding corresponding buffers. To support wide bandwidth clock generation, each component of the inner clock generation circuit must be able to perform over an extremely wide bandwidth. The inner clock generation circuit supports the wide bandwidth requirements by incorporating components designed from CMOS tri-state inverters, as set forth in more detail below, without inductive peaking elements. Although the receiver side is described in this disclosure, many of the same components are present in the transmitter side as well.

In the receiver inner clock generation circuit 200, reference clocks are supplied to each lane from PLL 201. CDR 202 is used to align the clock sampling edges to the center of the data. CDR 202 is also used to track part-per-million (ppm) offsets between the data and clock rates either by adjusting frequency or phase of the clocks. Selectable frequency divider 203 is used in the clocking architecture to support legacy standards, rather than alternatively turning off a portion of the data path (i.e., reducing first rank interleaving from 16 to 8). MPCG 204 and deskew stage 205 create the reference phases for the sampling circuits 208, 209. Duty-cycle limiter 206 generates 25% duty cycle clocks before rank 1 sampling circuit 208 to improve performance of the data path. Finally, PR 207 ensures rank 2 sampling circuit 209 occurs at the correct point. While this exact implementation is unique to this disclosure, the noteworthy features lie within the implementation, as set forth below.

CDR 202 must have high resolution and excellent linearity to negligibly contribute to the clocking jitter. As such, CDR 202 should be placed at the point in the clocking path where the narrowest bandwidth must be supported, and the minimum number of phases must be generated given the high-power cost per phase. Therefore, it is intuitive for CDR 202 to be placed first in the receiver inner clock generation before the selectable frequency divider 203 or MPCG 204. Modern CDRs are typically implemented with either Voltage Controlled Oscillators (VCOs) or Current Mode Logic (CML) Phase Rotators (PRs). These are common choices because of their low jitter derived from their tuned structures. Complementary metal oxide semiconductor (CMOS) structures have been used at past data rates, but their large area and power make them unpopular at 100-GS/s and beyond.

FIG. 2B is a layout diagram illustrating an exemplary, non-limiting embodiment of a receiver inner clock generation circuit in accordance with various aspects described herein. In an embodiment, inner clock generation circuit 200 described herein is illustrated in layout 210 that uses an area of 325 μm×100 μm. The best way to evaluate the complete clock path performance is by simulating it with the data path.

FIG. 2C comprises a chart showing a data path transfer function and simulated SNDR at select points. As shown in FIG. 2C, chart 220 shows the data path transfer function when using the clock path to drive the rank 1 and rank 2 track and hold sampling circuits. The output SNDR is measured to be 34.3 dB at the output which is down from 35.3 dB with an ideal clock path. This 1 dB degradation demonstrates the robust performance of the clock path in such a small area.

FIG. 2D comprises a chart summarizing total power consumption of an inner clock generation circuit in accordance with various aspects herein. As shown in FIG. 2D, chart 230 shows the total power consumption of the inner clock generation circuit operating at Fs=112-GS/s to be 95.1 mW, which is state-of-the-art for modern wireline transceivers.

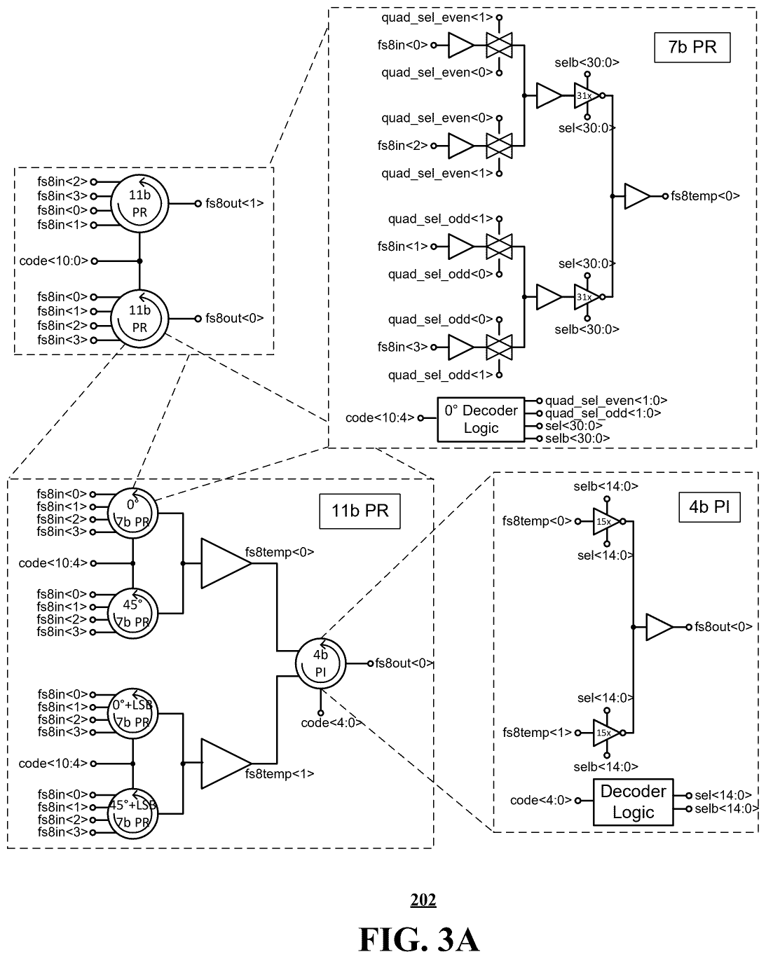

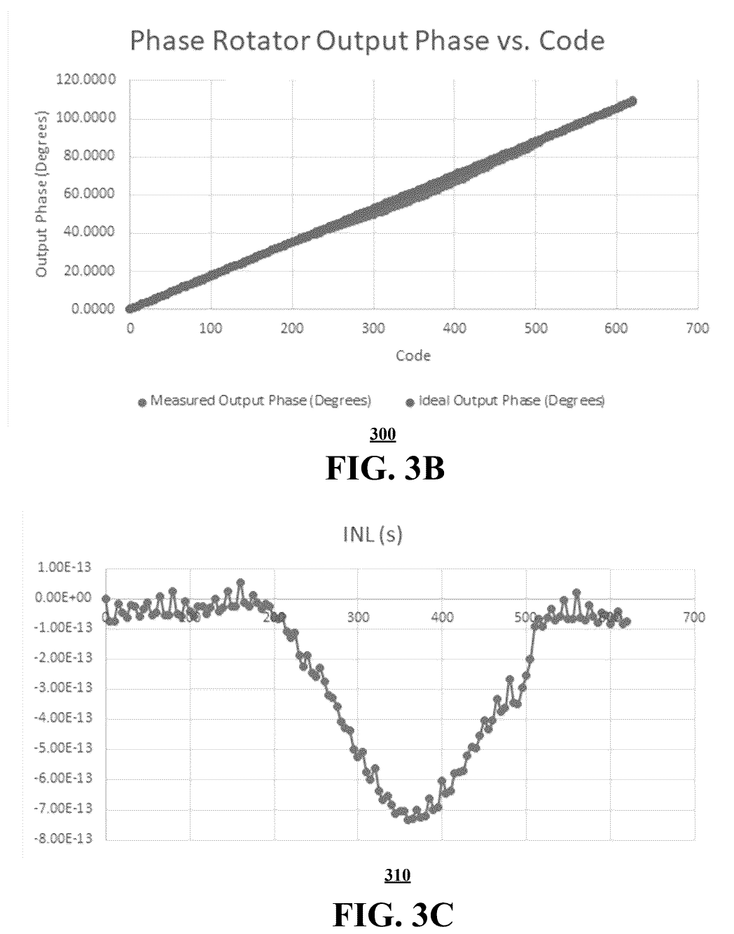

FIG. 3A is a schematic diagram illustrating an exemplary, non-limiting embodiment of a phase rotator used in a clock and data recovery loop in accordance with various aspects described herein. As shown in FIG. 3A, a PR is used in the clock and data recovery loop (CDR 202) illustrated in FIG. 2. In an embodiment, CDR 202 takes advantage of an 11-bit CMOS PR based on tri-state inverters that achieves low jitter, power and area while achieving a large bandwidth. The 11-bit CMOS PR of CDR 202 comprises four 7-bit PRs and a 4-bit phase interpolator (PI), as shown in FIG. 3A. The purpose of CDR 202 is to be able to move the clock in an extremely fine step size so that the data is sampled at the center point of the data, also known as the “eye” of the data. U.S. patent application Ser. No. 18/060,787 entitled, “Method and Apparatus for Clock and Data Alignment that Reduces Power Consumption,” filed on Dec. 1, 2022, which is incorporated by reference herein, provides more details about CDR 202.

FIG. 3B is a chart illustrating a linear performance of a phase rotator in accordance with various aspects described herein. As shown in FIG. 3B, chart 300 illustrates a measured output phase and an ideal output phase for a portion of the phase rotator codes.

FIG. 3C is a chart illustrating an integral non-linearity performance of a phase rotator in accordance with various aspects described herein. Chart 310 shows that the integral non-linearity (INL) reaches a peak-peak value of ˜700 fs, which translates directly to the peak-peak jitter during plesiochronous operation. However, this raw INL value is low enough that it can be easily corrected with a lookup table (LUT) so that it has no effect on system performance. The static jitter of the PR is measured to be about 100 fs (rms) and consumes ˜40 mA from a 0.65V supply. These metrics (area, linearity, jitter and power) meet requirements to be used in modern and legacy wireline transceivers.

Referring back to FIG. 2A, a selectable frequency divider 203 follows CDR 202 and is placed before MPCG 204 so that clock frequency division is performed on a limited number of phases. Hence, selectable frequency divider 203 can be used to reduce the number of phases generated by a phase clock generator by a factor of two, such that CDR 202 only needs to generate two phases and the selectable divider can perform quadrature phase generation for input to MPCG 204.

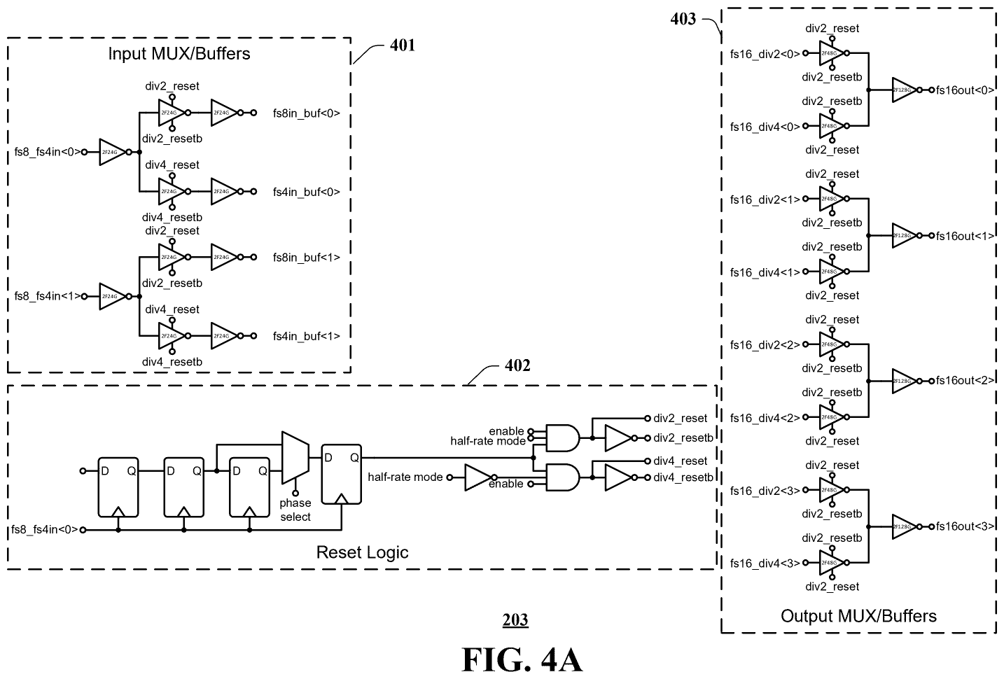

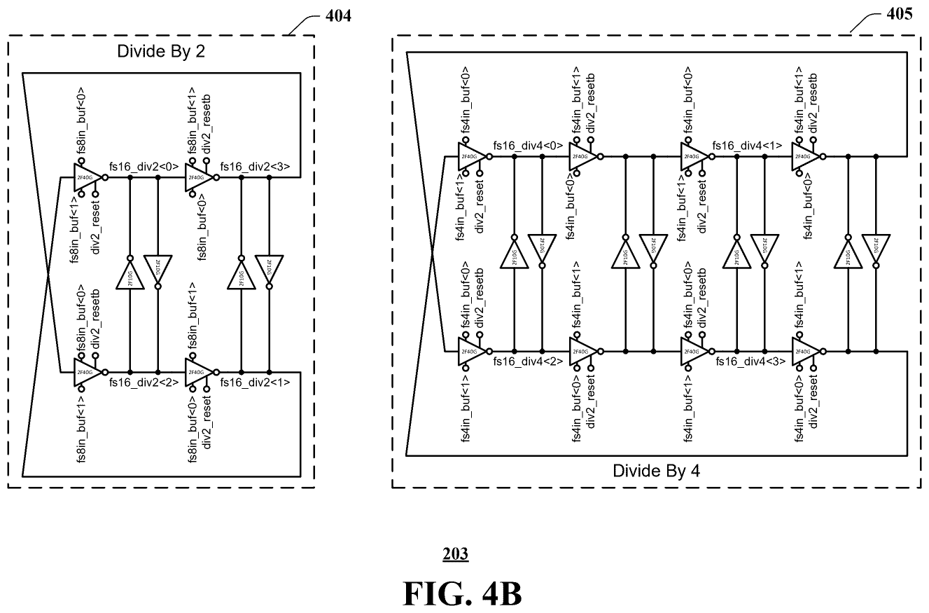

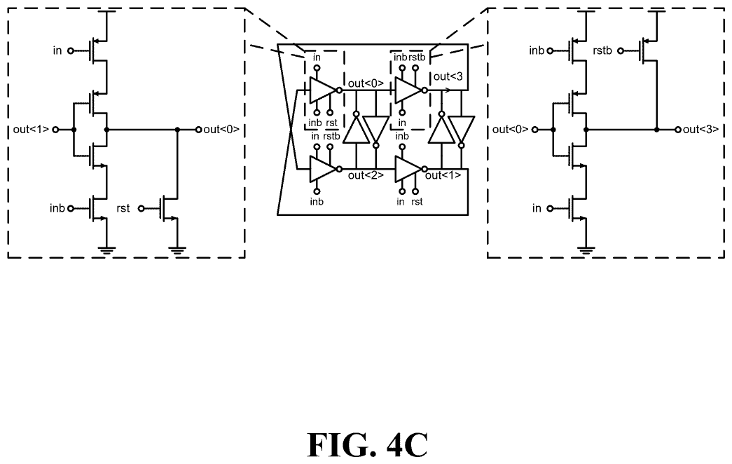

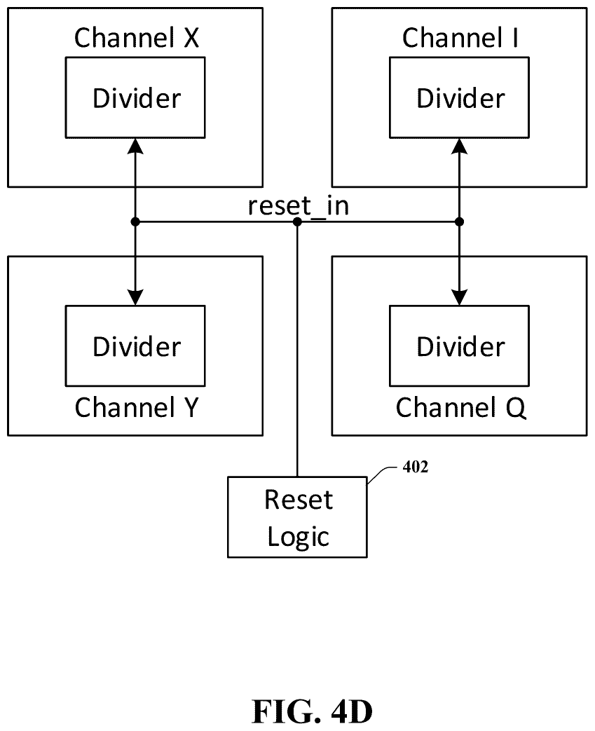

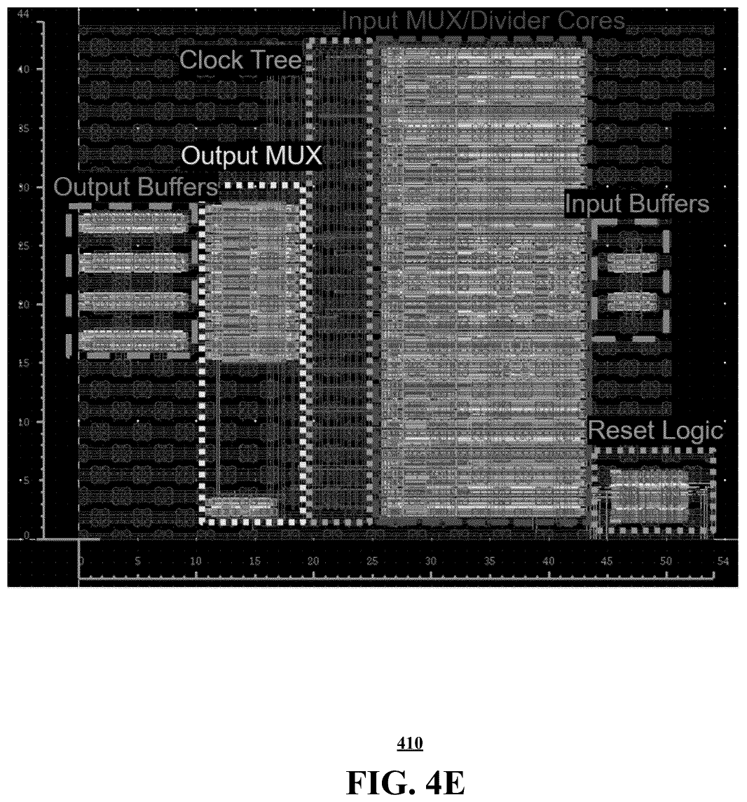

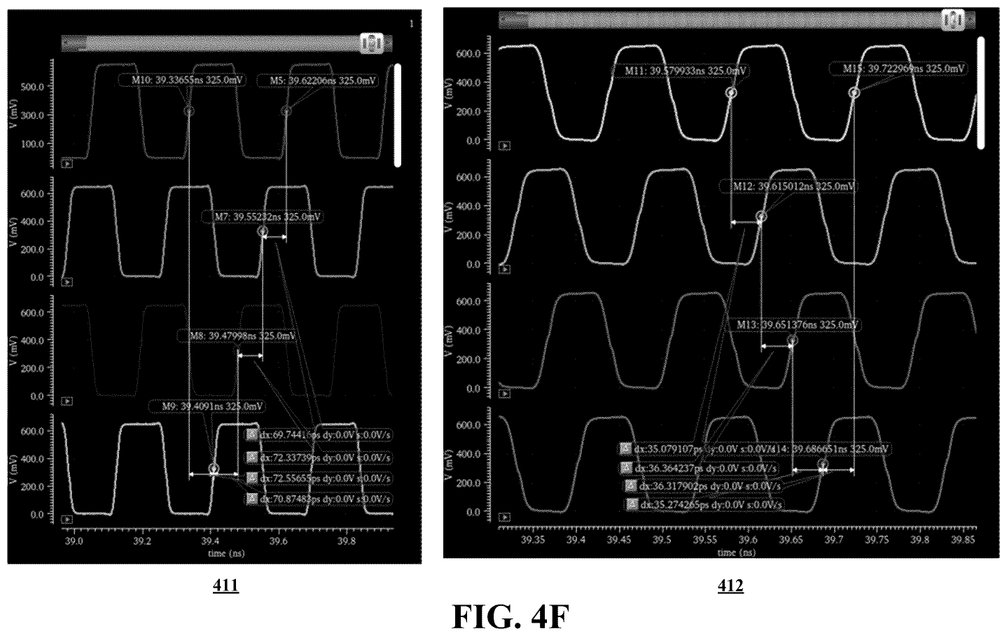

FIG. 4A is a schematic diagram illustrating an exemplary, non-limiting embodiment of circuit designs for a selectable divider in accordance with various aspects described herein. As shown in FIG. 4A, input multiplexers and buffers 401, reset logic 402, and output multiplexers and buffers 403 support a selectable frequency divider 203. There are many ways that a selectable divider may be implemented. For example, CML based dividers with inductive peaking are commonly used in wireline transceivers. Latch-based dividers are the most common implementation, but they have several shortcomings. There is an inherent asymmetry due to the feedback loop, and the divider starts up in an unknown (non-deterministic) state, so synchronizing many dividers to do multi-phase clock division is difficult. Ring-based injection locked frequency dividers (ring-ILFDs) are another solution for dividers. Ring-IFLDs are a better choice for multi-phase clock division since a single divider schematic is used and there is no need for synchronization within a channel. However, ring-ILFDs also do not inherently have a reset, hence they start up in an unknown state. Additionally, if synchronization of multiple dividers is required, there is no inherent ability to synchronize a ring-IFLD. While these shortcomings may be non-issues for electrical applications, they are critical features in optical applications where up to four channels (XYIQ) must be synchronized.

FIG. 4B is a schematic diagram illustrating resettable ring-based dividers that use CMOS elements to achieve a very wide bandwidth of operation in accordance with various aspects described herein. Divide-by-2 and divide-by-4 ring-based dividers 404 and 405 are illustrated in FIG. 4B. While being held in a reset state, dividers 404 and 405 do not consume any additional power. Hence, supporting divide-by-2, -4, -8, etc. is achieved with no additional cost of power, thereby making an attractive design for multi-rate support.

FIG. 4C is a schematic diagram illustrating resettable ring-based dividers in accordance with various aspects described herein. As shown in FIG. 4C, a CMOS-based ring-ILFD divider is implemented using tri-state inverters where the input clocks are passed into the gate of the “select” devices, which is incorporated into dividers 404, 405 of FIG. 4B. This design adds a pull-up gate or a pull-down gate to the tri-state inverters to reset the ILFD by pulling the output node either to VDD or ground. The pull-up or pull-down devices reset the divider into a deterministic state by alternating pull-up and pull-down devices between opposite phases.

FIG. 4D is a schematic diagram illustrating distribution of a reset signal to multiple channels of dividers in accordance with various aspects described herein. As shown in FIG. 4D, the reset signal can be used to synchronize dividers either within a channel or across channels. To do so, the reset signal must originate from a central destination and then be distributed to each divider in a tree-like manner, so that the reset signal reaches each divider at the same time. Referring to FIG. 4A, reset logic 402 includes a flip-flop to enable flipping the output phase of the divider. The multiplexers of input multiplexers and buffers 401 and output multiplexers and buffers 403 select between two paths. One path passes the reset signal straight through to the divider. The second path delays the reset signal by one input clock cycle using a flip-flop. One input clock cycle corresponds to half a clock cycle at the output in a divide by 2, so this added delay has the effect of resetting the divider in a flipped state (i.e., 0° and 180° are swapped). This feature can be used in place of pull-up/pull-down devices described above or as an additional safety mechanism to correct sampling if the divider starts up with a clock 180 degrees out of phase.

FIG. 4E is a layout diagram illustrating a resettable ring-based divider implemented in accordance with various aspects herein. FIG. 4E shows a complete layout 410 for a selectable divide-by-2 or -4 design combining all the features of selectable frequency divider 203 implemented on the Neutrino-T receiver inner clock generation. The selectable divider uses an area of 54 μm×44 μm.

FIG. 4F comprises charts showing functionality of a selectable divider implemented in accordance with various aspects herein. As shown in FIG. 4F, chart 411 indicates the jitter is 70 fs (rms) at full-rate and draws 15 mA of current from a 0.65V supply. Chart 412 illustrates the functionality at half-rate, which indicates the jitter is 80 fs (rms) and draws 11 mA of current from a 0.65V supply.

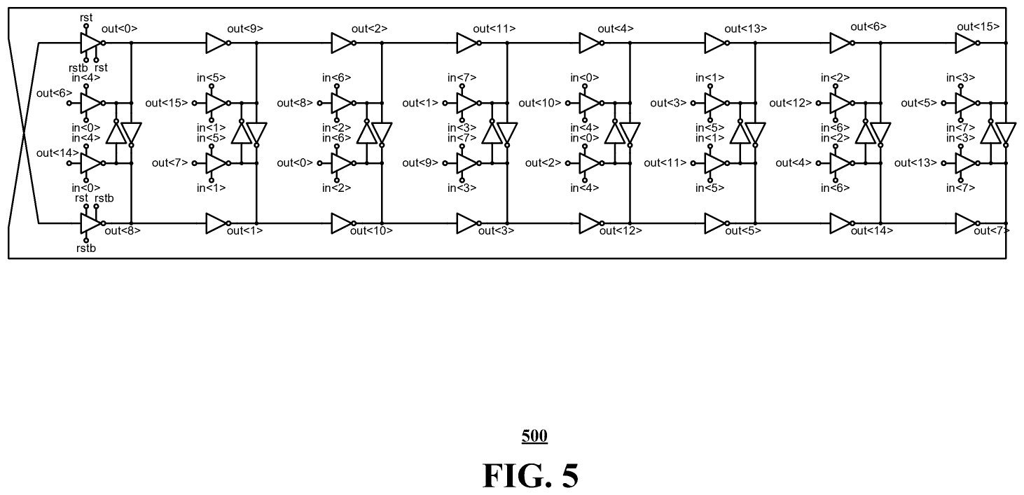

FIG. 5 is a schematic diagram illustrating an exemplary, non-limiting embodiment of a multipath ring oscillator injection locked frequency divider in accordance with various aspects described herein. As shown in FIG. 5, Multi-Path Ring Oscillator ILFD 500 (MPRO-ILFD) is a modification of an ILFD that can be used to reach high frequency operation independent of the number of input/output phases. This makes MPRO-ILFDs attractive for use on the transmitter side where distinct levels of serialization require many clock rates at the same time. As shown in FIG. 5, a divide-by-2 MPRO-ILFD 500, which is implemented on the transmitter side, uses pull-up/pull-down devices to reset the divider in a deterministic state. MPRO-IFLD 500 has logic to flip the output state and is synchronized across multiple channels. Each element has a very wide bandwidth, which allows for multi-rate support. Multi-rate support is very difficult to achieve while also meeting power, area and jitter standards, but is achieved by this design. Having a very wide bandwidth architecture is extremely beneficial because it allows complete reuse for modern and legacy data rates on both the electrical and optical side. Previously entirely different architectures would be required to support each rate. By enabling complete reuse, significant design hours can be saved, and more time can be spent on verification.

Referring back to FIG. 2A, MPCG 204 and deskew stage 205 follow selectable frequency divider 203 because duty-cycle limiter 206 is only needed at the rank 1 track-and-hold sampling circuit 208 because the rank 2 clock phases are controllable independent of the rank 1 clocks. There are many common forms of MPCG 204 and deskew stage 205, including Injection Locked Ring Oscillators (ILROs), Delay Locked Loops (DLLs), analog Phase Interpolators (PIs), and polyphase filters. But each of these forms present a challenge in one or more of the following areas: space, jitter, skew, bandwidth, power, complexity, and reliability. Multiphase clock generation for MPCG 204 and deskew stage 205 are based on digital PIs, as set forth in U.S. patent application Ser. No. 18/509,565 entitled, “Multiphase Clock Generator,” filed on even date herewith. This method of multiphase clock generation can achieve good usage regarding area, power, jitter and skew while performing well across a wide bandwidth, since the design is based on CMOS tri-state inverters.

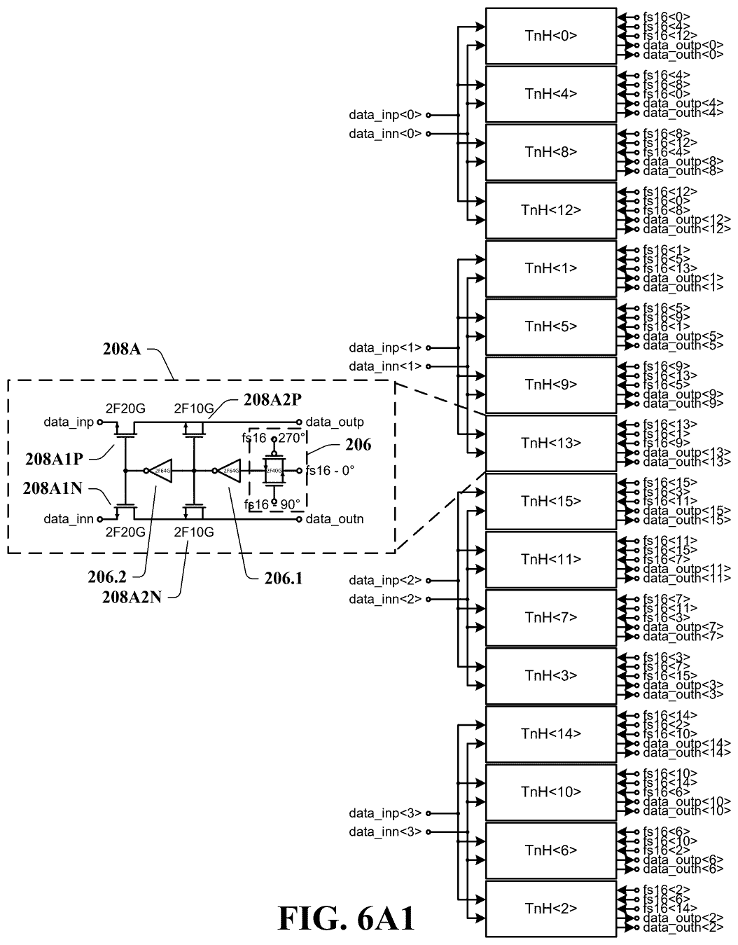

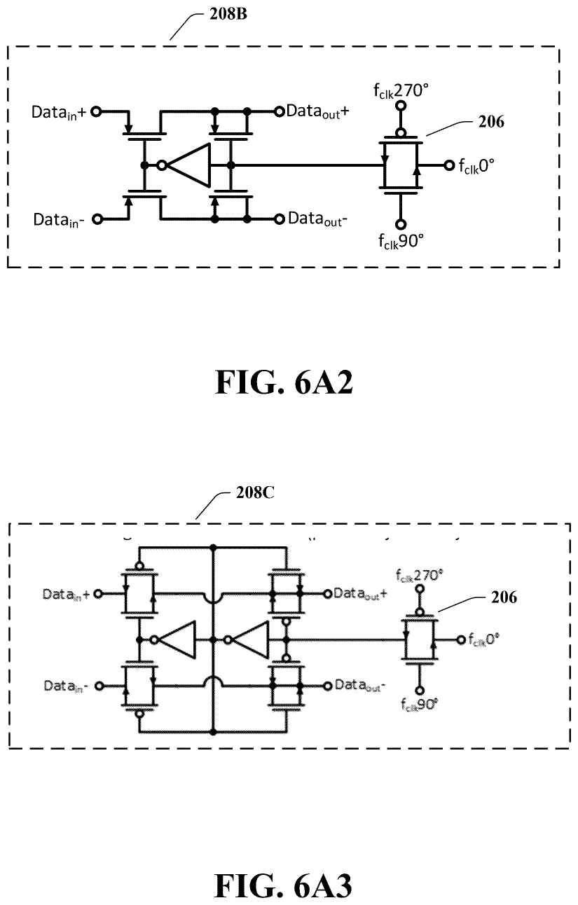

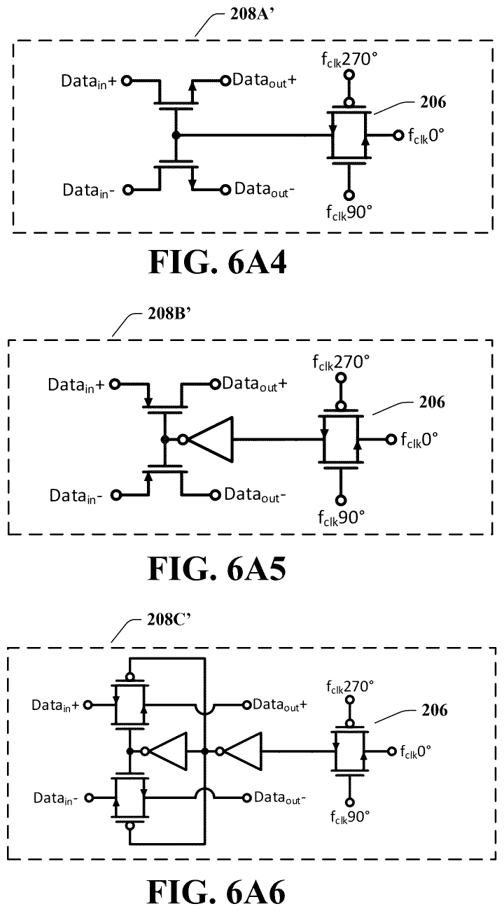

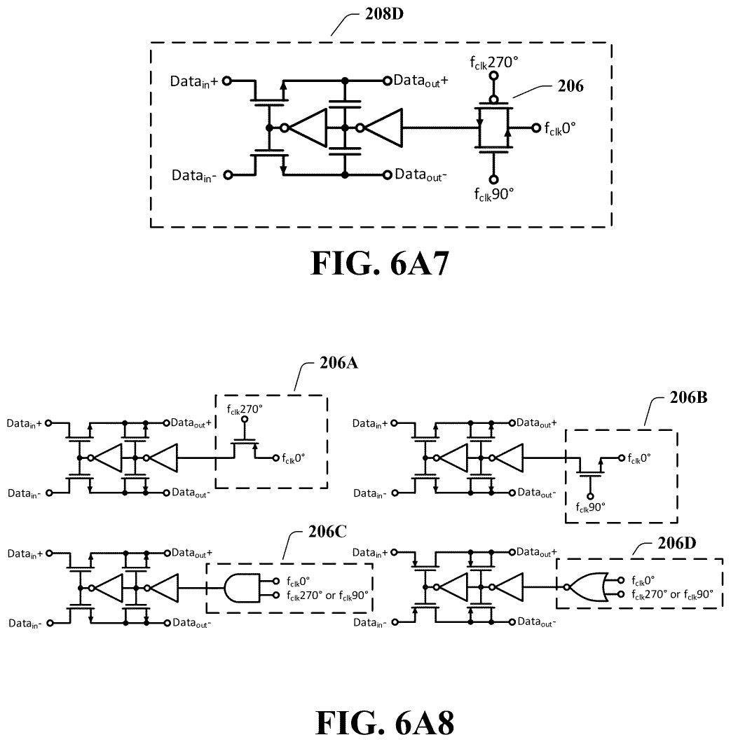

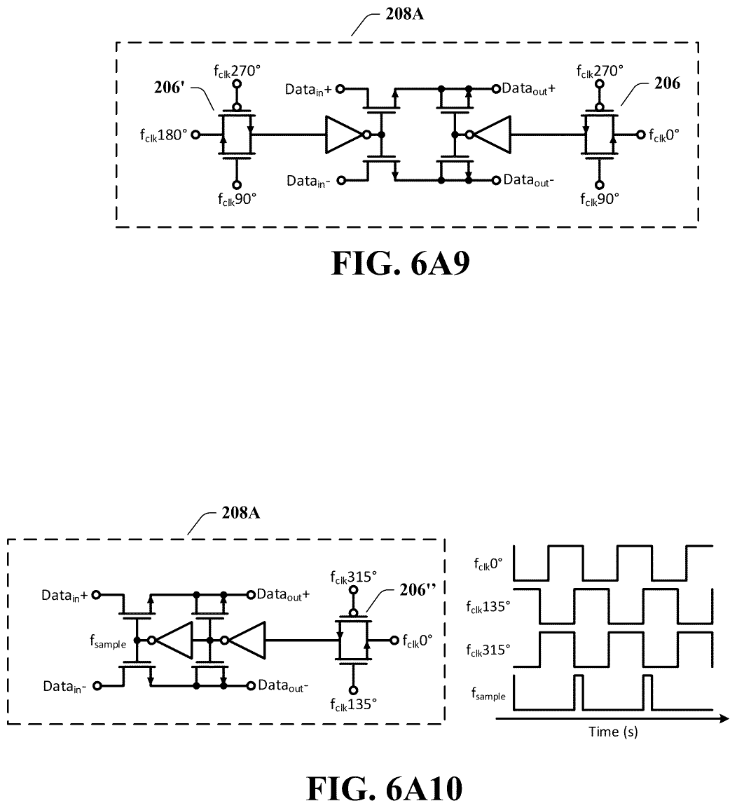

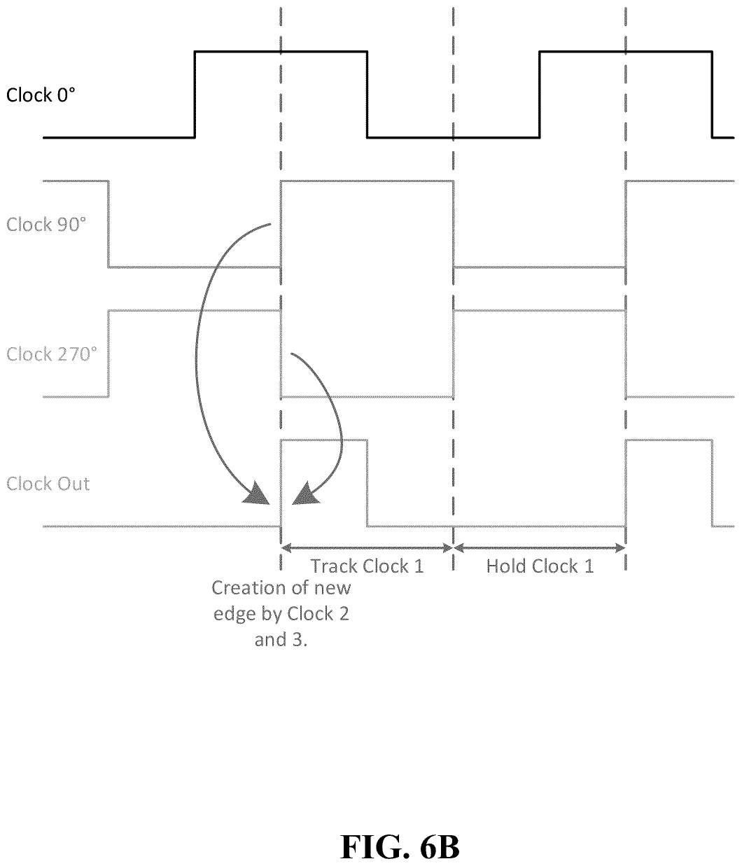

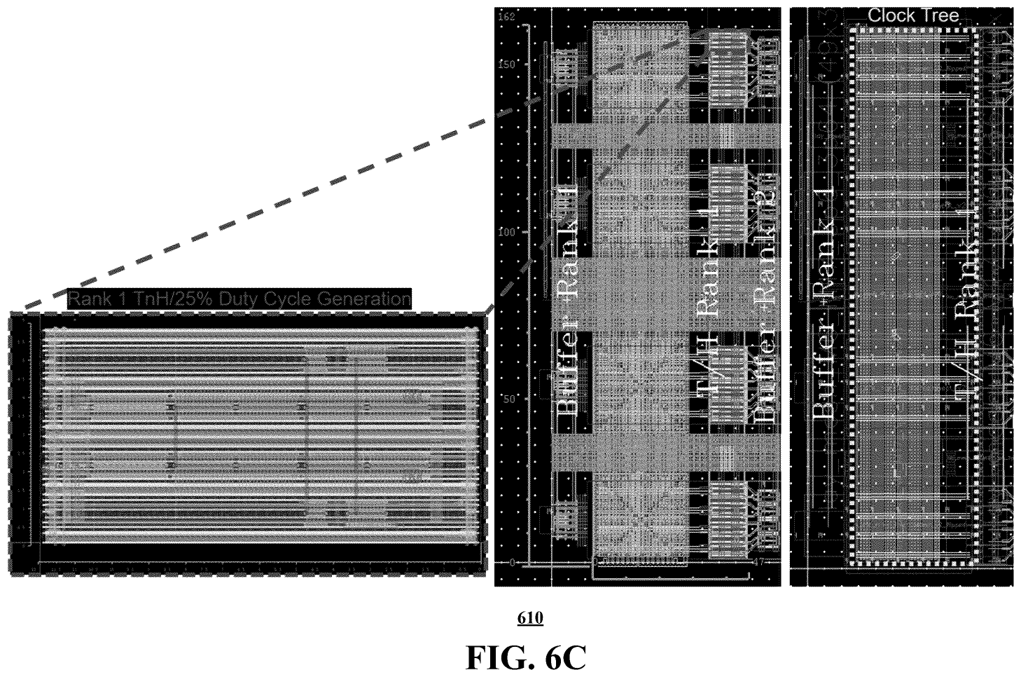

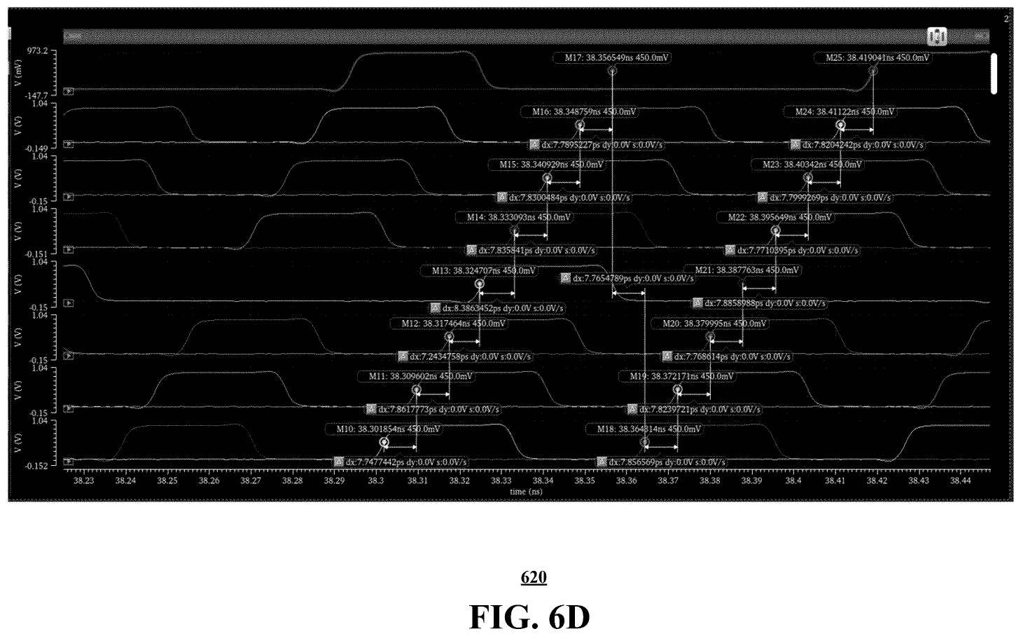

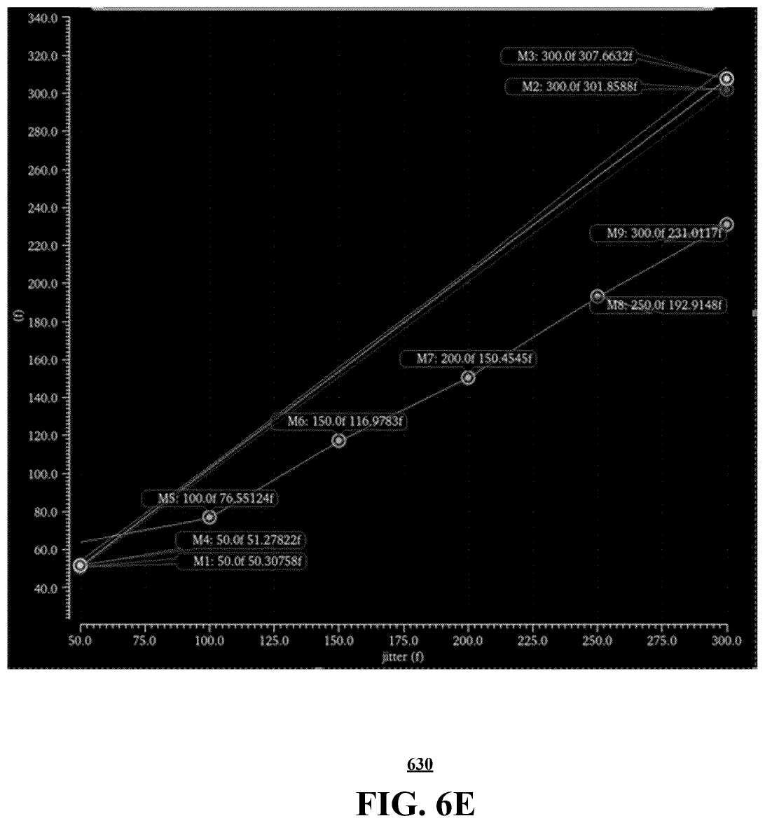

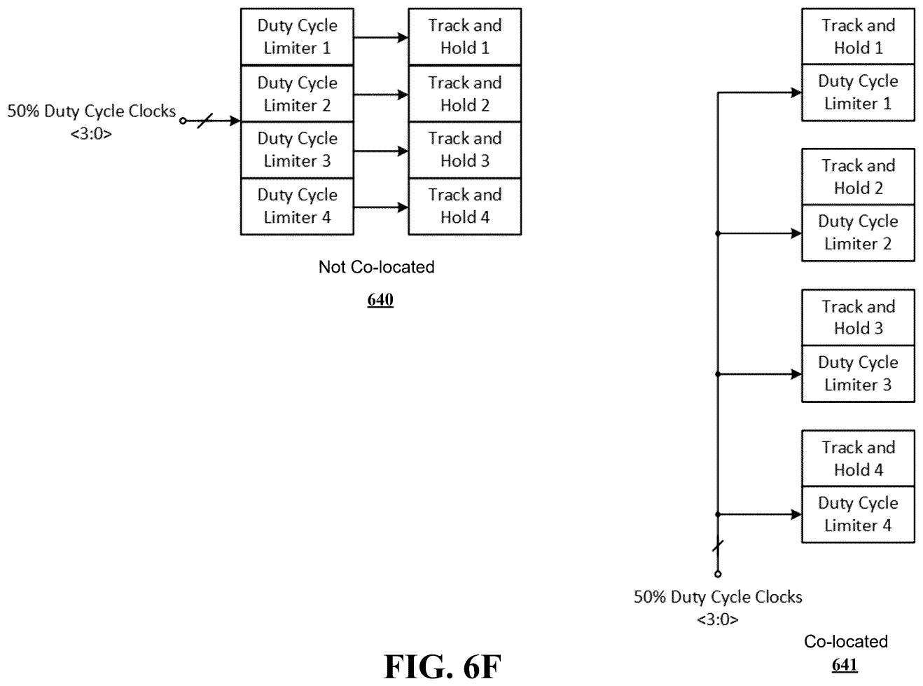

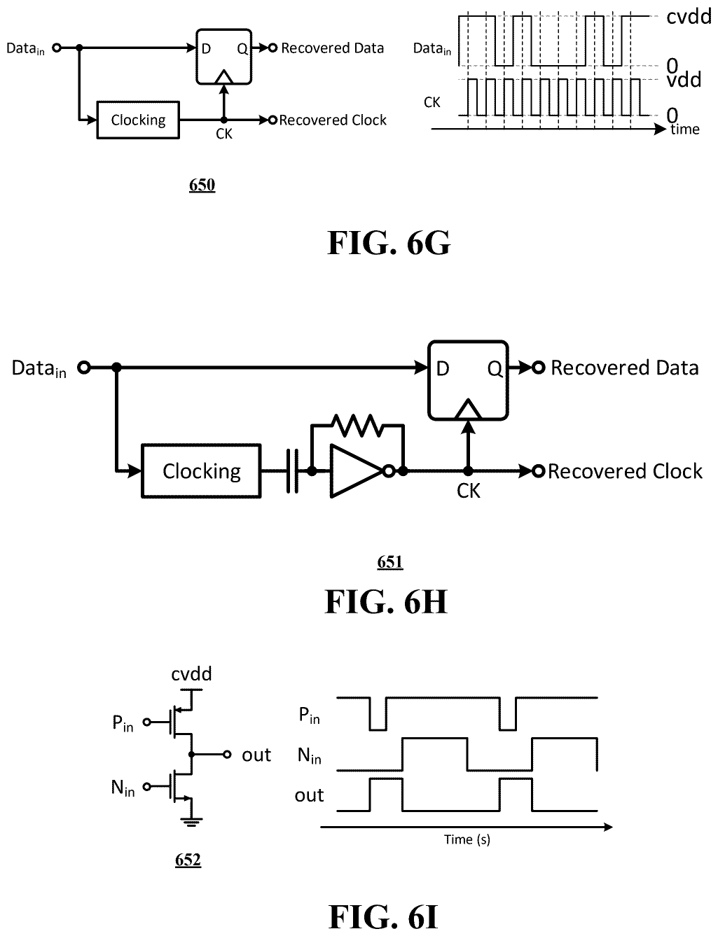

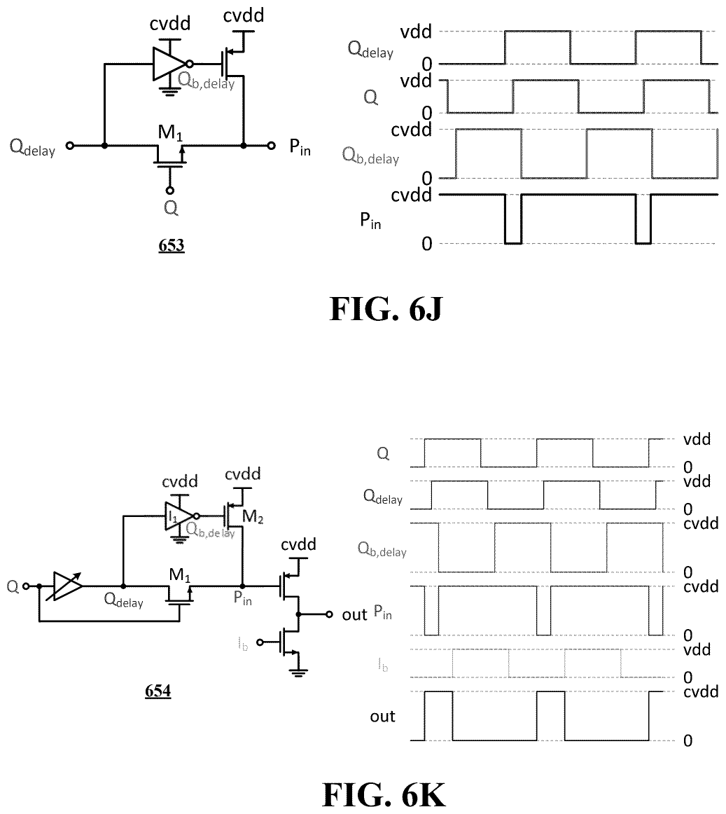

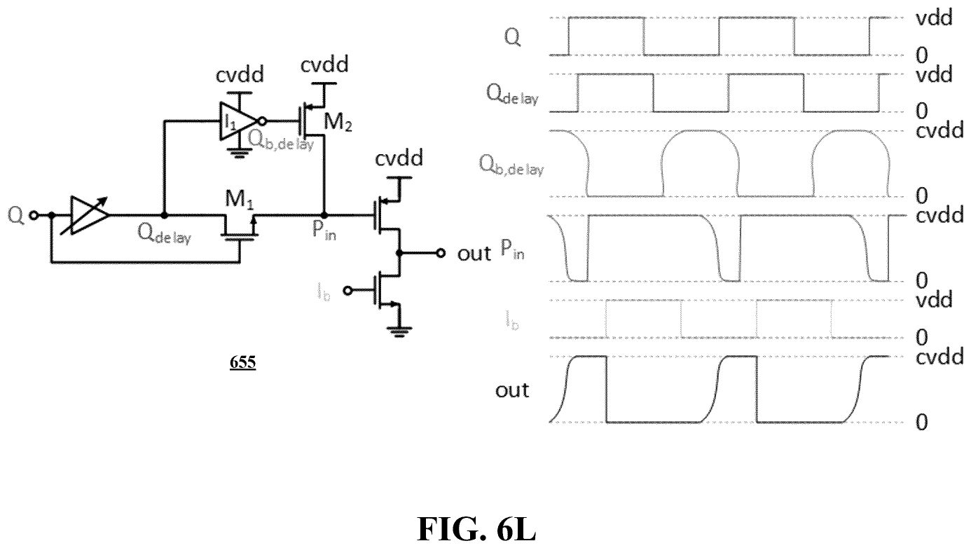

FIG. 6A1 is a schematic diagram illustrating an exemplary, non-limiting embodiment of a duty-cycle limiter incorporated in a track and hold sampling circuit in accordance with various aspects described herein. The duty-cycle limiter 206 can generate any duty cycle less than 100% based on available clock phases supplied at input and needs of the track and hold circuit 208. The duty cycle limiter circuit 206 is designed to receive available clock phases and create a duty cycle within a predefined range. This facilitates consistent performance and synchronized operation across interconnected circuits, avoiding signal distortion or mismatched timing. For example, as illustrated in FIG. 6A1, the track and hold sampling circuits 208A are arranged in groups of four so that clock feedthrough noise and kickback through the input signal channel is minimized in each group. Each track and hold sampling circuit in the group uses three of the same four quadrature clock signals. Because each track and hold sampling circuit in the group is located near each other, errors introduced by clock signal line length delay can be minimized in the design of each group. Further, deskew for line length delays of the high frequency clock generator to each group of track and hold sampling circuits can be handled by the deskew stage 205. Other arrangements may be contemplated with these principles in mind.

As shown in FIG. 6A1, track and hold sampling circuit 208A comprises complementary positive 208A1P and negative 208A1N input gates, collectively known as a sampling circuit. The sampling circuit tracks and samples data input signals and generates sampled data signals. The sampling circuit is coupled to the duty cycle clock signal generated by duty-cycle limiter 206 through a first inverter 206.1 and a second inverter 206.2. Complementary positive 208A1P and negative 208A1N input gates are triggered by the output of second inverter 206.2 to sample data. Track and hold sampling circuit 208A further comprises positive and negative gates 208A2P and 208A2N, collectively known as a charge injection cancelation device that receives the sampled data signals and provides output data signals. The charge injection cancelation device is triggered by the output of first inverter 206.1. In an embodiment, complementary positive 208A1P and negative 208A1N input gates and positive and negative gates 208A2P and 208A2N comprise n-type metal oxide semiconductors (MOS).

In the exemplary embodiment, by using a 25% duty cycle clock, only one of the four track and hold sampling circuits is actively tracking in the group at a time during a complete cycle, while the other three are held. There are many ways to perform 25% duty cycle generation, the most common of which is using an AND gate. In this implementation, duty-cycle limiter 206 generates a clock signal having a 25% duty cycle. The AND gate function is performed by a T-gate. The T-gate has a 90-degree clock connected to a N-doped terminal of a MOSFET, a 270-degree clock connected to a P-doped terminal of the MOSFET and a zero-degree clock connected to the gate of the MOSFET. The output of the T-gate is clock 90° and clock 270° and clock 0°. By using both the 90-degree clock and the 270-degree clock to manufacture the leading clock edge, the T-gate averages any jitter in either clock signal, thereby reducing jitter, as shown in FIG. 6E below.

By enabling tighter control over timing characteristics, the system reflects clear improvements over existing systems, as the claims illustrate advancements like duty cycle trimming, configurable clock generation, and reliable signal sampling. These features collectively contribute to enhanced computer operations through optimized internal timing for processing units. Additionally, they provide advancements in technical fields like telecommunications, aiding in high-fidelity signal transmission and synchronized network operations.

FIG. 6A2 is a schematic diagram illustrating an exemplary, non-limiting embodiment of a duty-cycle limiter incorporated in a track and hold sampling circuit in accordance with various aspects described herein. As shown in FIG. 6A2, track and hold sampling circuit 208B comprise p-type metal oxide semiconductors (MOS). The sampling circuit is coupled to the duty cycle clock signal generated by duty-cycle limiter 206 through a single inverter. By removing an inverter in the clock path, 75% duty cycle clocks are used by the sampling circuit of the pMOS track and hold sampling circuit 208B. Since the pMOS device tracks when the clock is low, the device will still use 25% sampling. A pMOS sampling device can be advantageous when the desired input and output common mode of the data is high. The charge injection cancelation device in track and hold sampling circuit 208B is triggered by the duty cycle clock signal.

FIG. 6A3 is a schematic diagram illustrating an exemplary, non-limiting embodiment of a duty-cycle limiter incorporated in a track and hold sampling circuit in accordance with various aspects described herein. As shown in FIG. 6A3, track and hold sampling circuit 208C comprise complementary metal oxide semiconductors (CMOS). The sampling circuit is coupled to the duty cycle clock signal generated by duty-cycle limiter 206 through a single inverter. A CMOS sampling device has advantages in noise-and-distortion generation compared to nMOS or pMOS devices and can be used when a mid-rail common mode is desired for the data path. The charge injection cancelation devices illustrated in FIGS. 6A1, 6A2 and 6A3 are used for charge injection and clock feedthrough cancellation and to help improve the distortion performance of the sampling. However, the charge injection cancelation devices come at the cost of extra loading on the data path and therefore bandwidth loss. These methods of 25% duty cycle generation can easily be extended to a track-and-hold without the charge injection cancelation devices, as illustrated in FIGS. 6A4, 6A5 and 6A6 below.

FIGS. 6A4, 6A5 and 6A6 are schematic diagrams illustrating exemplary, non-limiting embodiments of a duty-cycle limiter incorporated in a track and hold sampling circuit without charge injection cancelation devices in accordance with various aspects described herein. As shown in FIG. 6A4, track and hold sampling circuit 208A′ comprises nMOS, lacks a charge injection cancelation device, and is triggered directly from the duty cycle clock signal produced by duty-cycle limiter 206. As shown in FIG. 6A5, track and hold sampling circuit 208B′ comprises pMOS, lacks a charge injection cancelation device, and is triggered by the output of an inverter connected to the duty cycle clock signal generated by duty-cycle limiter 206. As shown in FIG. 6A6, track and hold sampling circuit 208C′ comprises CMOS and lacks a charge injection cancelation device. Removing the charge injection cancelation device reduces the loading on the track and hold sampling circuit, which improves the bandwidth by up to a few GHz or the loss at Nyquist by up to a few decibels. A drawback of removing the charge injection cancelation device is increased distortion, which can decrease the Signal to Distortion Ratio by a few decibels.

FIG. 6A7 is a schematic diagram illustrating an exemplary, non-limiting embodiment of a duty-cycle limiter incorporated in a track and hold sampling circuit with a capacitive charge injection cancelation device in accordance with various aspects described herein. As shown in FIG. 6A7, track and hold sampling circuit 208D is similar to the nMOS track and hold sampling circuit 208A illustrated in FIG. 6A1, but the charge injection cancelation device comprises two capacitors. The capacitors serve the same purpose for charge injection and clock feedthrough cancellation and to help improve the distortion performance of the sampling as the gates illustrated in FIG. 6A1.

FIG. 6A8 are schematic diagrams illustrating exemplary, non-limiting embodiments of alternative duty-cycle limiters incorporated in a track and hold sampling circuit in accordance with various aspects described herein. As shown in FIG. 6A8, the 25% duty cycle generation does not need to rely on a T-gate, but can use simple nMOS or pMOS based AND gates (as illustrated by duty-cycle limiters 206A and 206B), logical AND gates for nMOS samplers (as illustrated by duty-cycle limiter 206C) or logical NOR gates for pMOS samplers (as illustrated by duty-cycle limiter 206D). These methods of 25% duty cycle clock signal generation may result in more clock jitter but can save on clock loading and power. Any of the previously described track and hold sampling circuits can use these methods of duty cycle clock signal generation.

Clock feedthrough and charge injection cancellation rely on the fact that as the sampling device turns off, the charge injection cancelation device turns on, and the channel charge deposited by the sampling device is absorbed by the charge injection cancelation device. By using a single gate for 25% and 75% pulse generation, some delay between the sampling device turning off and the charge injection cancelation device turning on occurs due to the extra inverter delay. This delay negates some of the benefits of the charge injection cancelation device.

FIG. 6A9 is a schematic diagram illustrating an exemplary, non-limiting embodiment of a pair of duty-cycle limiters incorporated in a track and hold sampling circuit in accordance with various aspects described herein. As shown in FIG. 6A9, the sampling circuit of track and hold sampling circuit 208A is triggered by an output of a first inverter connected to a clock signal generated by a first duty-cycle limiter 206′, while the charge injection cancelation circuit of track and hold sampling circuit 208A is triggered by an output of a second inverter connected to the duty cycle clock signal generated by a second duty-cycle limiter 206. To overcome the delay mentioned above between the sampling device turning off and the charge injection cancelation device turning on, symmetric 25% and 75% pulse generation is achieved by the two duty-cycle limiters 206 and 206′. Symmetric pulse generation improves the signal-to-noise-and-distortion ratio of the sampled data but comes at the cost of additional clock loading. Symmetric pulse generation can be done with nMOS, pMOS or CMOS sampling devices and using any of the AND/NOR gate implementations.

FIG. 6A10 is a schematic diagram and a timing diagram illustrating an exemplary, non-limiting embodiment of a duty-cycle limiter incorporated in a track and hold sampling circuit in accordance with various aspects described herein. As shown in FIG. 6A10, duty-cycle limiter 206″ is clocked differently than as shown in FIG. 6A1. If a higher or lower duty cycle is desired at the track and hold sampling circuit, the clock ANDing can be modified. For example, in a 16-way rank 1 interleaving is desired with two rank 1 buffers and 12.5% duty cycle clock signals, these results can be achieved merely by rerouting the various clock signals to the duty-cycle limiter, as illustrated in FIG. 6A10. The duty cycle clock signal, fₛₐₘₚₗₑ, generated by the duty-cycle limiter 206″ is illustrated in the timing diagram.

FIG. 6B is a timing diagram illustrating the operation of a 25% duty cycle limiter in accordance with various aspects described herein. As shown in FIG. 6B, when phase 90° in duty-cycle limiter 306 goes high (and 270° low) a new edge is created as the output reaches equilibrium with phase 0°. The output continues to track phase 0° until phase 90° goes low (and 270° high) at which point the output is held low.

FIG. 6C is a layout diagram illustrating a 25% duty-cycle limiter implemented in accordance with various aspects herein. As shown in FIG. 6C, layout 610 illustrates that the 25% duty cycle generation is co-located with the data path.

FIG. 6D is a graph showing simulated performance of a 25% duty cycle limiter implemented in accordance with various aspects herein. As shown in FIG. 6D, graph 620 illustrates the simulated performance of the 25% duty-cycle limiter operating at 7 GHz. The 25% duty cycle generation generates ˜20 fs (rms) of jitter at full- and half-rate.

FIG. 6E is a graph showing jitter performance of a 25% duty-cycle limiter implemented in accordance with various aspects herein. As shown in FIG. 6E, graph 630 shows that the jitter measured at the output and input of the 25% duty-cycle limiter and a \sqrt{2} jitter reduction. The x-axis shows jitter that was injected into the track and hold while the y-axis illustrates simulated jitter at the track and hold sampling edge. In the case where the clocks are passed straight through buffers (i.e., no 25% duty cycle generation as represented by red, green, yellow lines), the graph shows a one-to-one relationship between the injected jitter and the simulated output jitter. In the case where the 25% duty cycle generation is used (as shown by the cyan line) the simulated output jitter has \sqrt{2} jitter reduction from the injected jitter, once the injected jitter passes a certain threshold (i.e., about ˜50 fs). This threshold is the base jitter that is injected by the subsequent clock buffers that follow the AND gate.

FIG. 6F bears block diagrams illustrating duty-cycle limiters that are not co-located and co-located with track and hold sampling circuits implemented in accordance with various aspects herein. As shown in FIG. 6E, diagram 640 shows duty-cycle limiters that are not co-located with track and hold sampling circuits. The duty-cycle limiters are located farther than a few tens of microns away from the track and hold sampling device. Beyond a few tens of microns, clock distribution lines may become obvious (long and using upper metal layers) and re-buffering may be required at the destination. Notably, all the duty-cycle limiters are grouped together.

FIG. 6A1 shows duty-cycle limiters that are co-located with track and hold sampling circuits. Notably, all the duty-cycle limiters are intertwined throughout the track and hold stage with which they are co-located. The duty-cycle limiters are within a few tens of microns from the track and hold sampling circuits. In an embodiment, co-located duty-cycle limiters are within 5 μm from the track and hold sampling circuit.

FIG. 6G is a simplified schematic diagram and a timing diagram illustrating an exemplary, non-limiting embodiment of clock signal generation and level shifting in accordance with various aspects described herein. Often in a transceiver, the clock circuitry operates from a lower voltage power supply for power efficiency while the data path will use a higher voltage power supply to accommodate large data swings and minimize distortion. As shown in FIG. 6G, circuit 650 uses a flip-flop to level-shift the clock signal, as shown in the timing diagram.

FIG. 6H is a schematic diagram illustrating an exemplary, non-limiting embodiment of clock signal generation and level shifting using an AC buffer in accordance with various aspects described herein. As shown in FIG. 6H, to level-shift and amplify the clock path without introducing duty cycle distortion, an AC coupled buffer under the data path supply can be used in the circuit 651. However, the use of AC coupling can consume a large area (due to the capacitor) and introduce unwanted jitter to the sampling clock.

FIG. 6I is a schematic diagram and a timing diagram illustrating an exemplary, non-limiting embodiment of clock signal generation and level shifting using two gates in accordance with various aspects described herein. As shown in FIG. 6I, level shifting clock generation circuit 652 uses two gates (a pMOS gate and an nMOS gate) to generate a full-swing clock pulse. When Pᵢₙ goes low the output is pulled to CVDD. When Nᵢₙ goes high the output is pulled to ground. The swing of Pᵢₙ's pulse is not critical if Pᵢₙ can turn the pMOS transistor on. The width of Pᵢₙ's pulse is also not critical if the pulse ends before the start of the rising edge of Nᵢₙ. Similarly, Nᵢₙ's width and swing are not critical if the nMOS transistor can turn on/off. What ends up setting the duty cycle of the output pulse is the time delta between the Pᵢₙ's falling edge and the Nᵢₙ's rising edge, as illustrated in the timing diagram.

FIG. 6J is a schematic diagram and a timing diagram illustrating an exemplary, non-limiting embodiment of a circuit for triggering a level shifting clock generation circuit in accordance with various aspects described herein. As shown in FIG. 6J, circuit 653 generates the Pᵢₙ signal for circuit 652 described above from the lower voltage clock signal Q generated by a transceiver. Circuit 653 acts as a NAND gate; when Q and Q_{b,delay} are both high Pᵢₙ is pulled low, but when Q_{b,delay} returns low, Pᵢₙ is once again pulled high, as shown in the timing diagram. Q_{delay} is a delayed version of the input clock Q. By using a variable delay for the generation of Q_{delay}, the falling edge of Pᵢₙ can be controlled in time thus controlling the eventual duty cycle of the output pulse.

FIG. 6K is a schematic diagram and a timing diagram illustrating an exemplary, non-limiting embodiment of a level shifting clock generation circuit in accordance with various aspects described herein. FIG. 6K illustrates an overall circuit 654 described above in connection with FIGS. 61 and 6J. As shown by the associated timing diagram, overall circuit 654 realizes the pulse generation and level-shifting of the sampling clock.

FIG. 6L is a schematic diagram and a timing diagram illustrating an exemplary, non-limiting embodiment of a level shifting clock generation circuit in accordance with various aspects described herein. Circuit 655 illustrated in FIG. 6L uses a low leakage/high threshold voltage device for the M₁ transistor. When the M₂ transistor is off (i.e., Q_{b,delay} is high), Pᵢₙ is not well-defined, and the voltage can slowly leak from CVDD downward, as shown in the timing diagram. This leakage results in the output pulse having a slow rising edge and ambiguous duty cycle. By using a low leakage/high threshold voltage device for M₁, the voltage at Pᵢₙ is held at CVDD with minimal drift and issues with the output pulse are resolved. Further, inverter I₁ should also be implemented as a low leakage/high threshold device (at least for a pMOS device) to help better define the Q_{b,delay} signal, thereby providing a sharper rising/falling edge and better definition of the duty cycle.

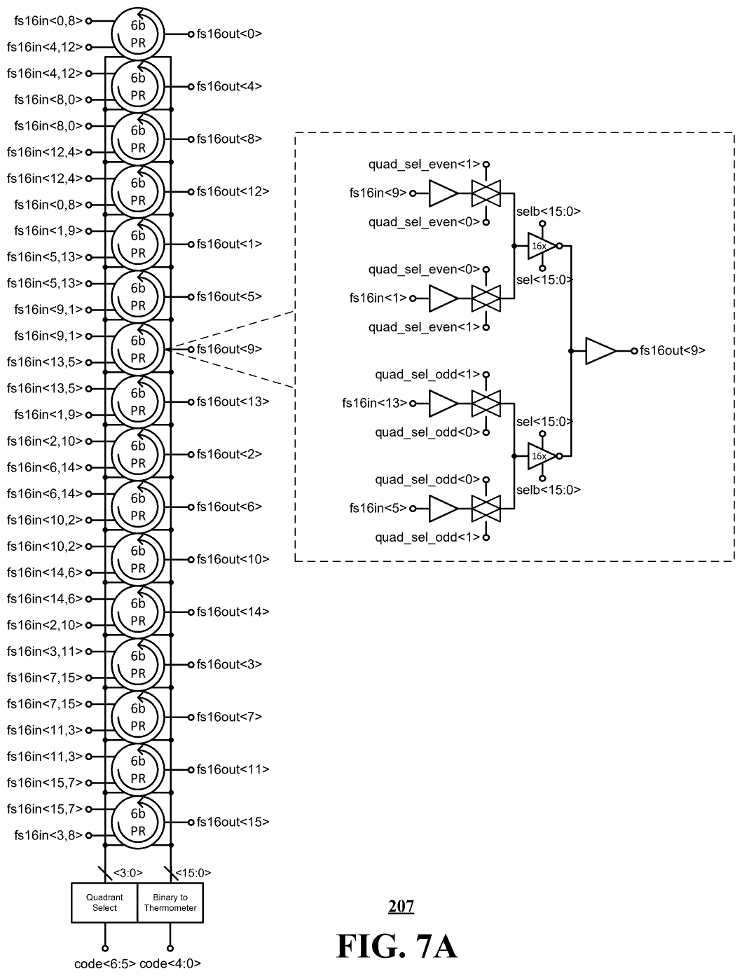

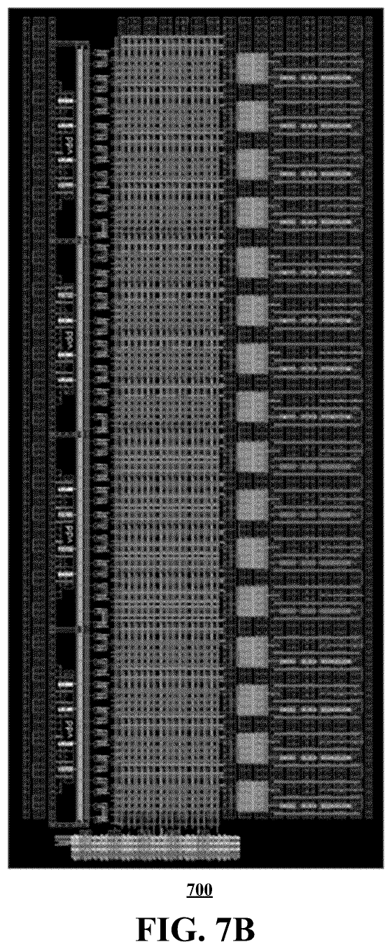

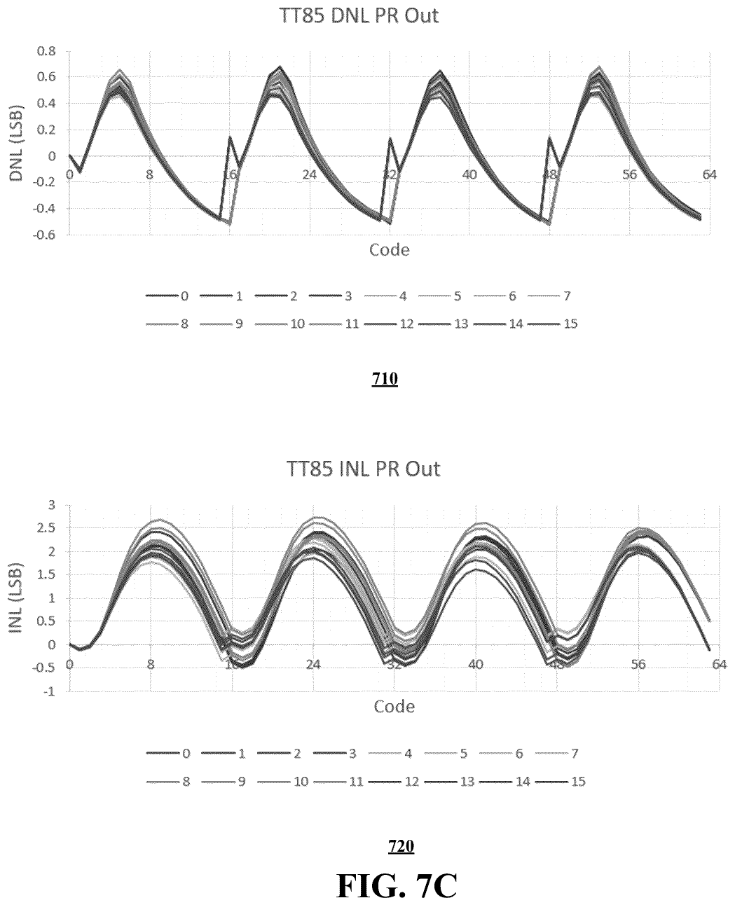

FIG. 7A is a schematic diagram illustrating an exemplary, non-limiting embodiment of a rank 2 phase rotator in accordance with various aspects described herein. Depending on the resolution required in the data path, PR 207 could be as simple as a barrel shifter that rotates the input clocks with no added resolution. In this implementation, 16 traditional CMOS PRs are in parallel to achieve wide bandwidth and low power.

FIG. 7B is a layout diagram illustrating a rank 2 phase rotator implemented in accordance with various aspects herein. FIG. 7B shows a complete layout 700 for PR 207, which occupies an area of 40 μm×100 μm.

FIG. 7C comprises charts showing differential non-linearity and integral non-linearity rank 2 phase rotator implemented in accordance with various aspects herein. As shown in FIG. 7C, chart 710 shows PR 207's differential non-linearity (DNL), which is simulated to be ±0.55 LSB. Chart 720 shows PR 207's integral non-linearity (INL), which is simulated to be ±1.5 LSB.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to,” “coupled to,” and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A track-and-hold sampling circuit, comprising:
a duty-cycle limiter that generates a clock signal having a duty cycle that is less than 100% from three out of four clock signals; and
a sampling circuit comprising complementary positive and negative input gates that track and sample data input signals, wherein the sampling circuit generates sampled data signals, wherein the complementary positive and negative input gates are coupled to the clock signal.

2. The track-and-hold sampling circuit of claim 1, wherein the complementary positive and negative input gates comprise n-type metal oxide semiconductors (MOS) triggered by the clock signal.

3. The track-and-hold sampling circuit of claim 2, further comprising: a charge injection cancelation device that receives the sampled data signals and provides output data signals.

4. The track-and-hold sampling circuit of claim 3, wherein the charge injection cancelation device comprises a capacitor.

5. The track-and-hold sampling circuit of claim 3, further comprising:
a first inverter that generates an inverted clock signal from the clock signal; and
a second inverter that generates a delayed clock signal from the inverted clock signal,
wherein the charge injection cancelation device is triggered by the inverted clock signal and wherein the sampling circuit is triggered by the delayed clock signal.

6. The track-and-hold sampling circuit of claim 1, wherein the duty-cycle limiter comprises a T-gate metal oxide semiconductor field effect transistor having an n-type terminal, a p-type terminal and a gate, wherein a first clock signal of the four clock signals is connected to the n-type terminal, a second clock signal of the four clock signals is connected to the p-type terminal and a third clock signal of the four clock signals is connected to the gate.

7. The track-and-hold sampling circuit of claim 1, wherein the four clock signals are quadrature clock signals, and the duty cycle is 25%.

8. The track-and-hold sampling circuit of claim 1, wherein when the four clock signals are operated at 7 GHz, the track-and-hold sampling circuit generates about 20 femtoseconds root mean square (RMS) of jitter at full or half rate.

9. The track-and-hold sampling circuit of claim 1, wherein when the duty-cycle limiter reduces jitter by a factor of a square root of two.

10. The track-and-hold sampling circuit of claim 1, wherein the duty-cycle limiter is co-located within the track-and-hold sampling circuit.

11. The track-and-hold sampling circuit of claim 10, wherein the duty-cycle limiter is located within 5 μm from the track-and-hold sampling circuit.

12. The track-and-hold sampling circuit of claim 1, further comprising a first clock inverter that generates an inverted clock signal from the clock signal, wherein the complementary positive and negative input gates comprise p-type metal oxide semiconductors (MOS) triggered by the inverted clock signal.

13. The track-and-hold sampling circuit of claim 12, further comprising a charge injection cancelation device that receives the sampled data signals and provides output data signals, wherein the charge injection cancelation device is triggered by the clock signal.

14. The track-and-hold sampling circuit of claim 1, further comprising:
a first inverter that generates an inverted clock signal from the clock signal; and
a second inverter that generates a delayed clock signal from the inverted clock signal,
wherein the complementary positive and negative input gates comprise complementary metal oxide semiconductors (CMOS) triggered by the delayed clock signal and the inverted clock signal.

15. The track-and-hold sampling circuit of claim 14, further comprising a dummy device that receives the sampled data signals and provides output data signals, wherein the dummy device is triggered by the clock signal.

16. The track-and-hold sampling circuit of claim 1, wherein the duty-cycle limiter comprises an nMOS gate, a pMOS gate, an AND gate with inverted inputs or a NOR gate with inverted inputs.

17. A method for creating a duty-cycle clock signal for triggering a sampling circuit, comprising:
applying a first clock signal to an n-type terminal of a T-gate, wherein the T-gate is a metal oxide semiconductor field effect transistor;
applying a second clock signal to a p-type terminal of the T-gate; and
applying a third clock signal to a gate of the T-gate, thereby creating the duty-cycle clock signal having a duty cycle that is less than 100%.

18. The method of claim 17, wherein the sampling circuit comprises either an n-type metal oxide semiconductors (MOS) triggered by the duty-cycle clock signal, a p-type MOS triggered by an inverted duty-cycle clock signal, or a CMOS.

19. The method of claim 17, wherein the first clock signal, the second clock signal and the third clock signal are selected from three out of four quadrature clock signals and the duty cycle is 25%.

20. A track-and-hold sampling circuit, comprising:
a first duty-cycle limiter that generates a first clock signal having a duty cycle that is less than 100% from three clock signals out of four clock signals supplied to the first duty-cycle limiter;
a second duty-cycle limiter that generates a second clock signal having a second duty cycle that is less than 100% from another three out of the four clock signals, where one of clock signals is different from the three clock signals supplied to the first duty-cycle limiter;
a sampling circuit comprising complementary positive and negative input gates that track and sample data input signals, wherein the sampling circuit generates sampled data signals, wherein the complementary positive and negative input gates are coupled to the first duty-cycle limiter through a first inverter; and
a charge injection cancelation device that receives the sampled data signals and provides output data signals, wherein the charge injection cancelation device is triggered by an output of a second inverter connected to the second duty-cycle limiter.
